(19) United States
(12) Patent Application Publication
(10) Pub. No.: US 2025/0048627 A1
(43) Pub. Date: Feb. 6, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Jaehyeok Heo, Suwon-si (KR); Kyoung-Ho Kim, Suwon-si (KR); Hojun Lee, Suwon-si (KR); Sungsu Moon, Suwon-si (KR); Sea Hoon Lee, Suwon-si (KR); Jaeduk Lee, Suwon-si (KR); Junhee Lim, Suwon-si (KR)

(21) Appl. No.: 18/427,977

(22) Filed: Jan. 31, 2024

(30) Foreign Application Priority Data
Jul. 31, 2023 (KR) 10-2023-0100105

(51) Int. Cl. H10B 43/27; H01L 25/065; H10B 43/10; H10B 43/35; H10B 43/40; H10B 80/00

(52) U.S. Cl. CPC H10B 43/27; H01L 25/0652; H10B 43/10; H10B 43/35; H10B 43/40; H10B 80/00; H01L 2225/06506

(57) ABSTRACT

Disclosed are semiconductor devices and electronic systems including the same. The semiconductor device includes a substrate that has a recess region, a gate electrode on a bottom surface of the recess region, a gate dielectric layer between the gate electrode and the bottom surface of the recess region, a plurality of shield electrodes on laterally opposite sides of the gate electrode and on inner sidewalls of the recess region, a plurality of dielectric patterns between the shield electrodes and the inner sidewalls of the recess region, a plurality of impurity regions in the substrate and on opposite sides of the shield electrodes, and a channel region in the substrate and below the bottom surface of the recess region.

### CROSS-REFERENCE TO RELATED APPLICATION(S)

This U.S. nonprovisional application claims priority under 35 U.S.C. § 119 to Korean Patent Application No. 10-2023-0100105 filed on Jul. 31, 2023 in the Korean Intellectual Property Office, the disclosure of which is hereby incorporated by reference in its entirety.

### BACKGROUND

The present inventive concepts relate generally to a semiconductor device, and more particularly, to a nonvolatile three-dimensional semiconductor device including a vertical channel structure, a method of fabricating the same, and an electronic system implementing the same.

It is necessary to have a semiconductor device capable of storing a large amount of data in an electronic system which requires data storage. A semiconductor device has been highly integrated to meet high performance and low manufacturing cost which are required by customers. Integration of typical two-dimensional or planar semiconductor devices is primarily determined by the area occupied by a unit memory cell, such that it is greatly influenced by the level of technology for forming fine patterns. However, the extremely expensive processing equipment needed to increase pattern fineness may set a practical limitation on increasing the integration of the two-dimensional or planar semiconductor devices. Therefore, there have been proposed three-dimensional semiconductor memory devices having three-dimensionally arranged memory cells.

### SUMMARY

Some embodiments of the present inventive concepts provide a semiconductor device having improved electrical properties and increased reliability.

Some embodiments of the present inventive concepts provide an electronic system including a semiconductor device having improved electrical properties and increased reliability.

Objects of the present inventive concepts are not limited to those mentioned above, and other objects which have not been mentioned above will be clearly understood to those skilled in the art from the following description.

According to some embodiments of the present inventive concepts, a semiconductor device may comprise: a substrate that has a recess region; a gate electrode on a bottom surface of the recess region; a gate dielectric layer between the gate electrode and the bottom surface of the recess region; a plurality of shield electrodes on opposite sides of the gate electrode and on inner sidewalls of the recess region; a plurality of dielectric patterns between the respective plurality of shield electrodes and the inner sidewalls of the recess region; a plurality of impurity regions in the substrate and on opposite sides of the shield electrodes; and a channel region in the substrate and below the bottom surface of the recess region.

According to some embodiments of the present inventive concepts, a semiconductor device may comprise: a substrate that includes a cell array region and a contact region, the substrate having a recess region; a peripheral circuit structure on a top surface of the substrate and including a plurality of peripheral circuit transistors; a stack structure that includes a plurality of interlayer dielectric layers and a plurality of electrodes, the interlayer dielectric layers and the electrodes being alternately stacked on the peripheral circuit structure; and a plurality of vertical channel structures that extend into the stack structure. The peripheral circuit transistors may include a first peripheral circuit transistor and a second peripheral circuit transistor. The first peripheral circuit transistor may include: a first gate electrode on a bottom surface of the recess region; and a plurality of shield electrodes on opposite sides of the first gate electrode and inner sidewalls of the recess region.

According to some embodiments of the present inventive concepts, an electronic system may comprise: a semiconductor device that includes a substrate having a recess region, a peripheral circuit structure including a peripheral circuit transistor on the substrate, a cell array structure including a stack structure on the peripheral circuit transistor, and an input/output pad electrically connected to the peripheral circuit transistor; and a controller electrically connected through the input/output pad to the semiconductor device, the controller controlling the semiconductor device. The peripheral circuit transistor may include: a gate dielectric layer on a bottom surface of the recess region; a gate electrode on the gate dielectric layer; a plurality of dielectric patterns on inner sidewalls of the recess region; and a plurality of shield electrodes between the dielectric patterns and the gate electrode.

### BRIEF DESCRIPTION OF DRAWINGS

Embodiments will be more clearly understood from the following detailed description taken in conjunction with the accompanying drawings, wherein like reference numerals (when used) indicate corresponding elements throughout the several views, and in which:

FIG. 1 illustrates a simplified schematic diagram showing an example electronic system including a semiconductor device according to some embodiments of the present inventive concepts;

FIG. 2 illustrates a simplified perspective view showing an example electronic system including a semiconductor device according to some embodiments of the present inventive concepts;

FIGS. 3 and 4 illustrate cross-sectional views respectively taken along lines I-I′ and II-II′ of FIG. 2, showing a semiconductor device according to some embodiments of the present inventive concepts;

FIG. 5 illustrates a plan view showing an upper surface of an example semiconductor device according to some embodiments of the present inventive concepts;

FIGS. 6 and 7 illustrate cross-sectional views respectively taken lines I-I′ and II-II′ of FIG. 5, showing a semiconductor device according to some embodiments of the present inventive concepts;

FIGS. 8A to 8D illustrate enlarged cross-sectional views of section A depicted in FIG. 6, partially showing a semiconductor device according to some embodiments of the present inventive concepts;

FIG. 9 illustrates an enlarged cross-sectional view of section B depicted in FIG. 6, partially showing a semiconductor device according to some embodiments of the present inventive concepts;

FIGS. 10 and 11 illustrate cross-sectional views respectively taken lines I-I′ and II-II′ of FIG. 5, showing a semiconductor device according to some embodiments of the present inventive concepts;

FIG. 12 illustrates an enlarged cross-sectional view of section C depicted in FIG. 10, partially showing a semiconductor device according to some embodiments of the present inventive concepts;

FIGS. 13 to 18 illustrate cross-sectional views showing intermediate processes in an example method of fabricating a semiconductor device according to some embodiments of the present inventive concepts; and

FIGS. 19 to 21 illustrate cross-sectional views showing intermediate processes in an example method of fabricating a semiconductor device according to some embodiments of the present inventive concepts.

### DETAILED DESCRIPTION

The following will now describe one or more embodiments of the present inventive concepts with reference to the accompanying drawings. Like reference numerals may indicate like components throughout the description.

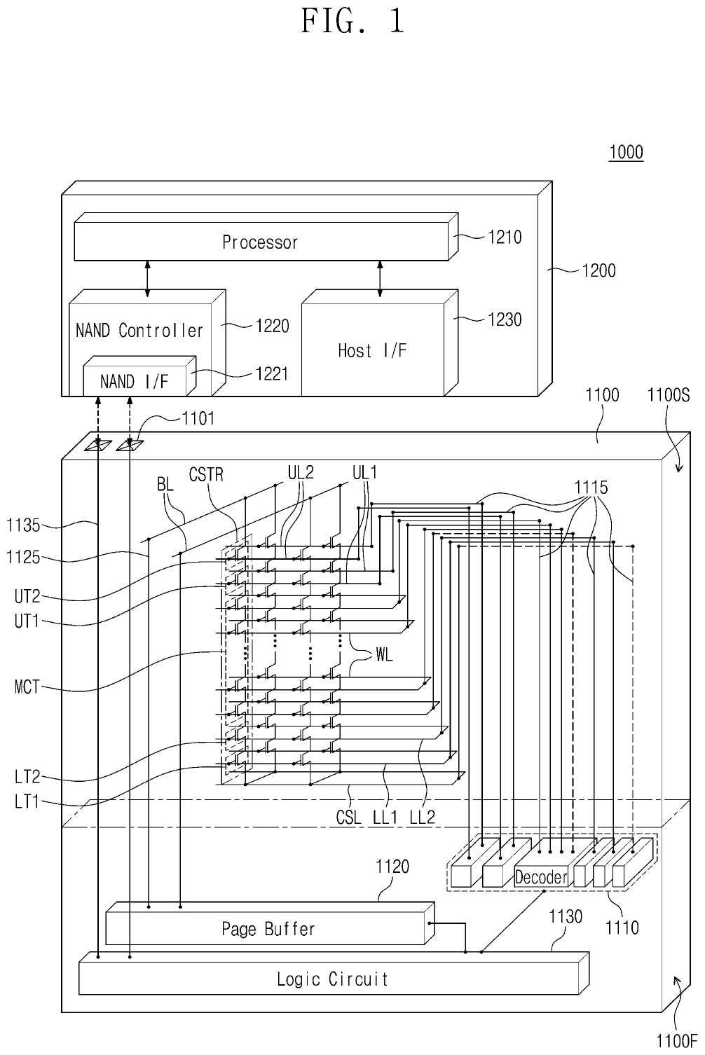

FIG. 1 illustrates a simplified schematic diagram showing an example electronic system including a three-dimensional semiconductor memory device, according to one or more embodiments of the present inventive concepts.

Referring to FIG. 1, an electronic system 1000 according to some embodiments of the present inventive concepts may include a semiconductor device 1100 and a controller 1200 electrically connected to the semiconductor device 1100. The term “connected” (or “connecting,” “contact,” “contacting,” or like terms), as may be used herein, is intended to refer to a physical and/or electrical connection between two or more elements, and may include other intervening elements. As used herein, the term “and/or” includes any and all combinations of one or more of the associated listed items. The electronic system 1000 may be a storage device that includes a single or a plurality of semiconductor devices 1100, or may be an electronic device that includes the storage device. For example, the electronic system 1000 may be, for example, a solid-state drive (SSD) device, a universal serial bus (USB), a computing system, a medical apparatus, or a communication apparatus, each of which includes a single or a plurality of semiconductor devices 1100.

The semiconductor device 1100 may be a nonvolatile memory device, such as a NAND flash memory device. The semiconductor device 1100 may include a first structure 1100F and a second structure 1100S on the first structure 1100F. Alternatively, the first structure 1100F may be disposed on a side of the second structure 1100S.

The first structure 1100F may be, for example, a peripheral circuit structure that includes a decoder circuit 1110, a page buffer 1120, and a logic circuit 1130. The second structure 1100S may be a memory cell structure that includes one or more bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to a corresponding one of the bit lines BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed in accordance with embodiments.

The upper transistors UT1 and UT2 may include string selection transistors, and the lower transistors LT1 and LT2 may include ground selection transistors. The first and second gate lower lines LL1 and LL2 may be gate electrodes of the lower transistors LT1 and LT2, respectively. The word lines WL may be gate electrodes of the memory cell transistors MCT, and the first and second gate upper lines UL1 and UL2 may be gate electrodes of the upper transistors UT1 and UT2, respectively.

For example, the lower transistors LT1 and LT2 may include a lower erase control transistor and a ground selection transistor that are connected in series. The upper transistors UT1 and UT2 may include a string selection transistor and an upper erase control transistor that are connected in series. One or both of the lower and upper erase control transistors may be employed to perform an erase operation in which a gate-induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115 that extend (e.g., vertically) from the first structure 1100F toward the second structure 1100S. The bit lines BL may be electrically connected to the page buffer 1120 through second connection lines 1125 that extend from the first structure 1100F to the second structure 1100S.

In the first structure 1100F, the decoder circuit 1110 and the page buffer 1120 may perform a control operation to at least one selection memory cell transistor among the plurality of memory cell transistors MCT. The logic circuit 1130 may control the decoder circuit 1110 and the page buffer 1120. The semiconductor device 1100 may communicate with the controller 1200 through one or more input/output pads 1101 electrically connected to the logic circuit 1130. The input/output pad(s) 1101 may be electrically connected to the logic circuit 1130 through one or more corresponding input/output connection lines 1135 that extend from the first structure 1100F to the second structure 1100S.

Although not explicitly shown, the first structure 1100F may include a voltage generator. The voltage generator may produce program voltages, read voltages, pass voltages, and verification voltages (or other control signals) that are required for operating the memory cell strings CSTR. The program voltage may be relatively higher (e.g., about 20 V to about 40 V) than the read voltage, the pass voltage, and the verification voltage.

For example, the first structure 1100F may include high-voltage transistors and low-voltage transistors. The decoder circuit 1110 may include pass transistors connected to the word lines WL of the memory cell strings CSTR. The pass transistors may include high-voltage transistors capable of withstanding high voltages such as program voltages applied to the word lines WL in a program operation. The page buffer 1120 may also include high-voltage transistors capable of withstanding high voltages.

The controller 1200 may include a processor 1210, a NAND controller 1220, and a host interface (I/F) 1230. For example, the electronic system 1000 may include a plurality of semiconductor devices 1100, and in this case, the controller 1200 may be configured to control the plurality of semiconductor devices 1100.

The processor 1210 may be configured to control an overall operation of the electronic system 1000 that includes the controller 1200. The processor 1210 may operate based on predetermined firmware, and may control the NAND controller 1220 to access the semiconductor device 1100. The NAND controller 1220 may include a NAND interface 1221 that is configured to communicate with the semiconductor device 1100. For example, the NAND interface 1221 may be used to transfer therethrough a control command to control the semiconductor device 1100, data intended to be written to the memory cell transistors MCT of the semiconductor device 1100, and/or data intended to be read from the memory cell transistors MCT of the semiconductor device 1100. The host interface 1230 may provide the electronic system 1000 with communication with an external host (not explicitly shown). When a control command is received through the host interface 1230 from the external host, the semiconductor device 1100 may be controlled by the processor 1210 in response to the control command.

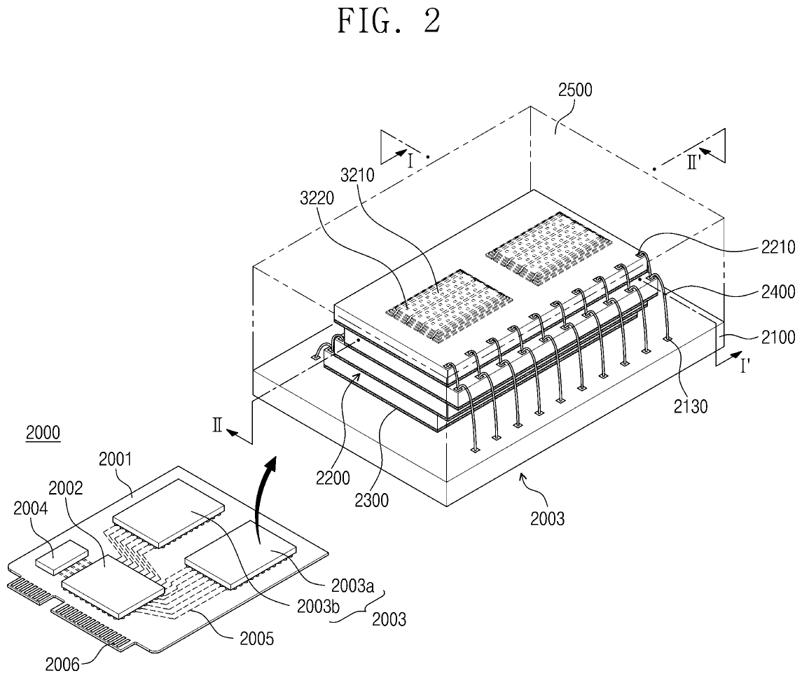

FIG. 2 illustrates a simplified perspective view showing an example electronic system including a three-dimensional semiconductor memory device according to one or more embodiments of the present inventive concepts.

Referring to FIG. 2, an electronic system 2000 according to some embodiments of the present inventive concepts may include a main board 2001, a controller 2002 mounted on the main board 2001, one or more semiconductor packages 2003, and a dynamic random-access memory (DRAM) 2004. The semiconductor package(s) 2003 and the DRAM 2004 may be connected to the controller 2002 through wiring patterns 2005 formed on the main board 2001.

The main board 2001 may include a connector 2006 including a plurality of pins that are coupled to an external host (not explicitly shown). The number and/or arrangement of the plurality of pins on the connector 2006 may be changed based on a communication interface between the electronic system 2000 and an external host. The electronic system 2000 may communicate with the external host through one or more interfaces, for example, universal serial bus (USB), peripheral component interconnect express (PIC-Express), serial advanced technology attachment (SATA), and M-PHY for universal flash storage (UFS). In addition, the electronic system 2000 may operate with power supplied through the connector 2006 from an external host. The electronic system 2000 may further include a power management integrated circuit (PMIC) by which the power supplied from the external host is distributed to the controller 2002 and the semiconductor package(s) 2003.

The controller 2002 may write data to the semiconductor package(s) 2003, may read data from the semiconductor package(s) 2003, and/or may increase an operating speed of the electronic system 2000.

The DRAM 2004 may be, for example, a buffer memory that is configured to compensate for a difference in speed between the external host and the semiconductor package(s) 2003 that serves as a data storage space. The DRAM 2004 included in the electronic system 2000 may operate as a kind of cache memory, and may provide a space for temporary data storage in a control operation of the semiconductor package 2003. When the DRAM 2004 is included in the electronic system 2000, the controller 2002 may include not only a NAND controller for controlling the semiconductor package 2003, but also a DRAM controller for controlling the DRAM 2004.

The semiconductor package(s) 2003 may include first and second semiconductor packages 2003a and 2003b that are spaced apart from each other on the main board 2001. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesion layers 2300 disposed on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400. The term “covers” (or “covering”, or like terms), as may be used herein, is intended to broadly refer to an element, structure or layer that is on or over another element, structure or layer, either directly or with one or more other intervening elements, structures or layers therebetween.

The package substrate 2100 may be a printed circuit board including upper pads 2130. Each of the semiconductor chips 2200 may include one or more input/output pads 2210. The input/output pads 2210 may correspond to the input/output pads 1101 of FIG. 1. Each of the semiconductor chips 2200 may include gate stack structures 3210 and vertical channel structures 3220. Each of the semiconductor chips 2200 may include a three-dimensional semiconductor memory device according to some embodiments of the present inventive concepts.

For example, the connection structures 2400 may include bond wires that electrically connect the input/output pads 2210 to the upper pads 2130. Therefore, in each of the first and second semiconductor packages 2003a and 2003b, the semiconductor chips 2200 may be electrically connected to each other in a bonding wire manner, and may be electrically connected to the upper pads 2130 of the package substrate 2100. Alternatively, in each of the first and second semiconductor packages 2003a and 2003b, the semiconductor chips 2200 may be electrically connected to each other through connection structures such as through silicon vias (TSVs) instead of, or in addition to, the connection structures 2400 implemented with bond wires.

For example, the controller 2002 and the semiconductor chips 2200 may be included in a single package. In some embodiments, the controller 2002 and the semiconductor chips 2200 may be mounted on a discrete interposer substrate other than the main board 2001, and may be electrically connected through wiring lines formed on the interposer substrate.

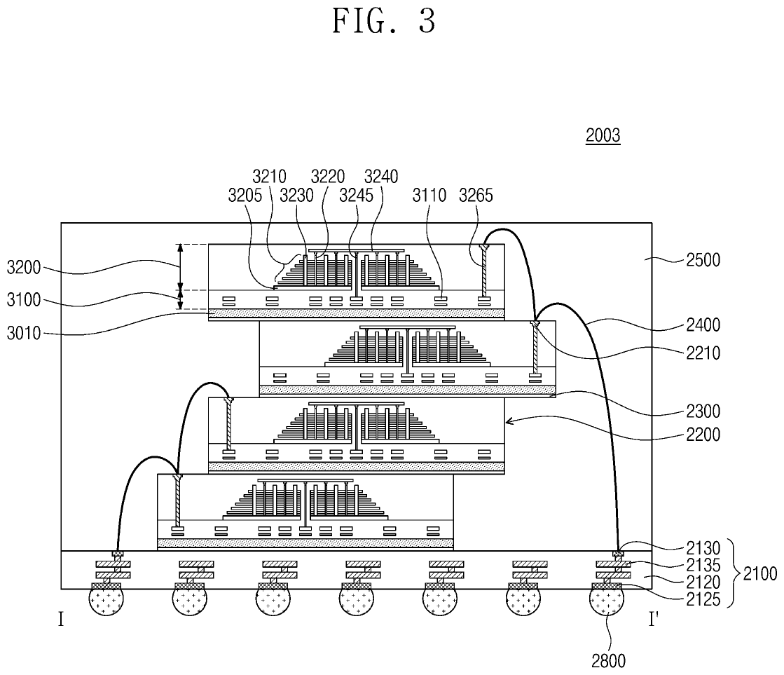

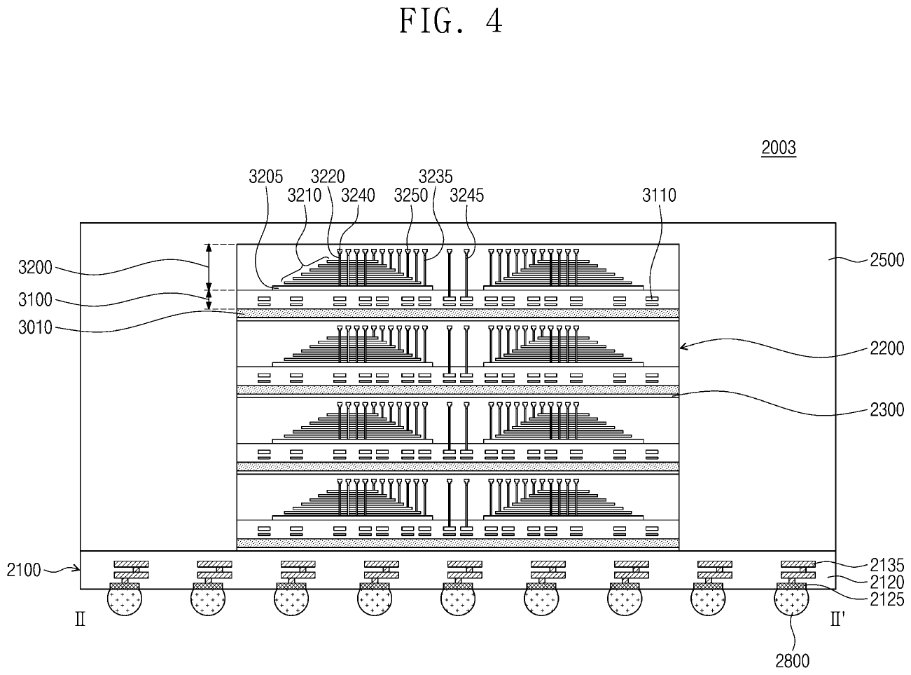

FIGS. 3 and 4 illustrate cross-sectional views respectively taken along lines I-I′ and II-III′ of FIG. 2, showing a three-dimensional semiconductor memory device according to one or more embodiments of the present inventive concepts.

Referring to FIGS. 3 and 4, the semiconductor package 2003 may include a package substrate 2100, a plurality of semiconductor chips 2200 stacked vertically on the package substrate 2100 (i.e., perpendicular an upper surface of the package substrate 2100), and a molding layer 2500 that covers (i.e., on or over) the package substrate 2100 and the plurality of semiconductor chips 2200.

The package substrate 2100 may include a package substrate body 2120, upper pads 2130 disposed on a top surface of the package substrate body 2120, lower pads 2125 disposed or exposed on a bottom surface of the package substrate body 2120, and internal wiring lines 2135 that lie in the package substrate body 2120 and electrically connect the upper pads 2130 to the lower pads 2125. The term “exposed” (or “expose,” or like terms) may be used to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. The upper pads 2130 may be electrically connected to a plurality of connection structures 2400. The lower pads 2125 may be connected through conductive connectors 2800 to the wiring patterns 2005 in the main board 2001 of the electronic system 2000 depicted in FIG. 2.

Each of the semiconductor chips 2200 may include a semiconductor substrate 3010, and may also include a first structure 3100 and a second structure 3200 that are sequentially stacked on the semiconductor substrate 3010 in a vertical direction (e.g., a direction perpendicular to the substrate). The first structure 3100 may include a peripheral circuit region including peripheral wiring lines 3110. The second structure 3200 may include a common source line 3205, a gate stack structure 3210 on the common source line 3205, vertical channel structures 3220 and separation structures 3230 that extend vertically into the gate stack structure 3210, bit lines 3240 electrically connected to the vertical channel structures 3220, gate connection lines 3235 and conductive lines 3250 that are electrically connected to word lines (see WL of FIG. 1) of the gate stack structure 3210.

Each of the semiconductor chips 2200 may include one or more through wiring lines 3245 that extend vertically into the second structure 3200 and are electrically connected to the peripheral wiring lines 3110 of the first structure 3100. The through wiring line 3245 may penetrate (i.e., extend into) the gate stack structure 3210, and may further be disposed laterally (i.e., in a horizontal direction parallel to the upper surface of the package substrate 2100) outside the gate stack structure 3210. Each of the semiconductor chips 2200 may further include an input/output connection line 3265 that extends vertically into the second structure 3200 and is electrically connected to the peripheral wiring lines 3110 of the first structure 3100, and may also further include input/output pads 2210 electrically connected to the input/output connection line 3265.

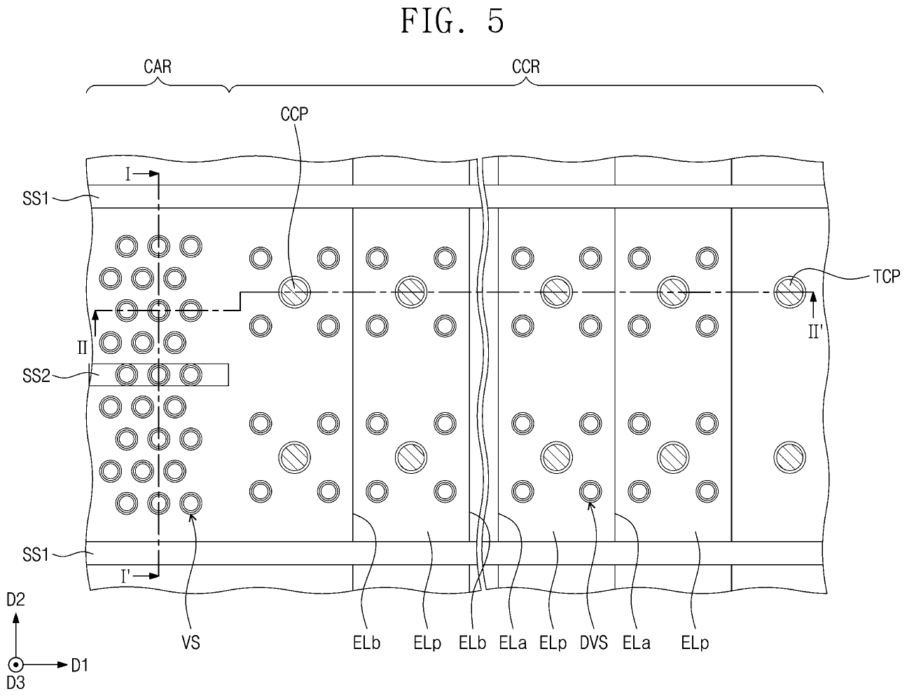

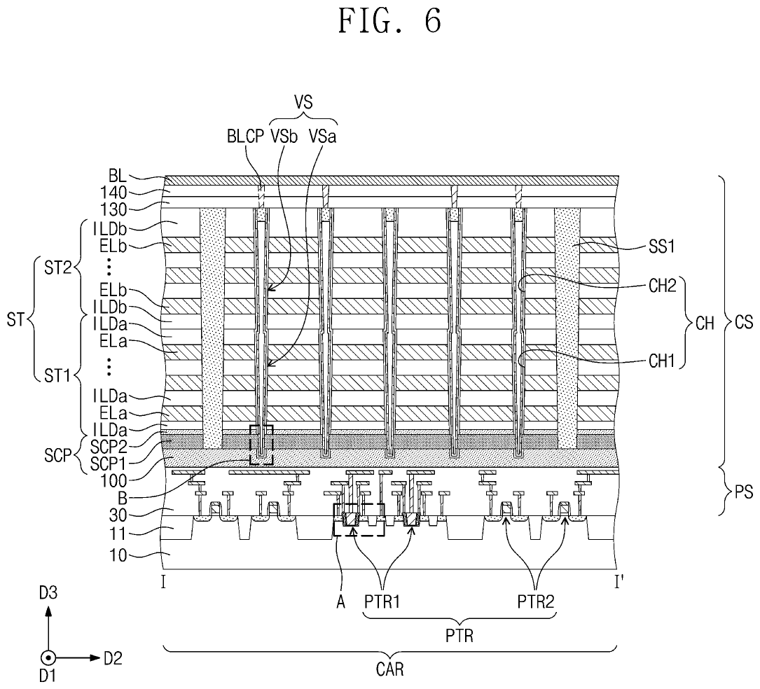

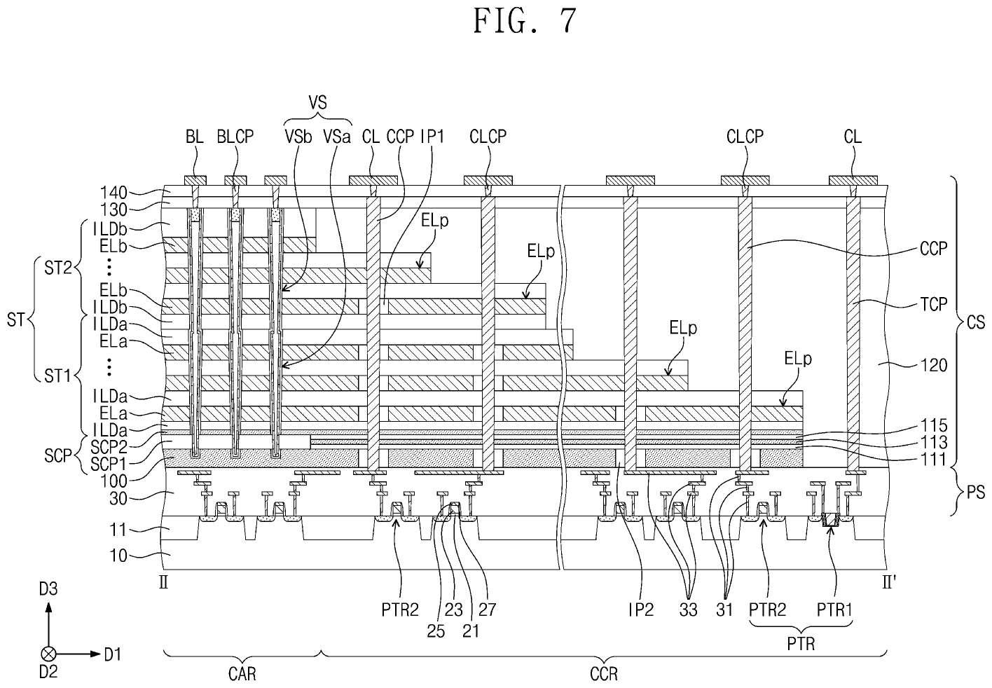

FIG. 5 illustrates a plan view showing a top surface of an example semiconductor device according to one or more embodiments of the present inventive concepts. FIGS. 6 and 7 illustrate cross-sectional views respectively taken lines I-I′ and II-II′ of FIG. 5, showing a semiconductor device according to some embodiments of the present inventive concepts.

Referring to FIGS. 5, 6, and 7, the present inventive concepts may provide a semiconductor device. For example, a semiconductor device of the present inventive concepts may be a three-dimensional semiconductor memory device. The semiconductor device may include a first substrate 10, a peripheral circuit structure PS on the first substrate 10, and a cell array structure CS on the peripheral circuit structure PS.

The first substrate 10 may include a cell array region CAR and a contact region CCR. The first substrate 10 may extend in a first direction D1 directed from the cell array region CAR toward the contact region CCR and in a second direction D2 that intersects the first direction D1. A top surface of the first substrate 10 may be parallel to the first direction D1 and the second direction D2, and may be perpendicular to a third direction D3 that intersects the first direction D1 and the second direction D2. For example, the first, second, and third directions D1, D2, and D3 may be orthogonal to each other; the first and second directions D1, D2 may be first and second horizontal directions, respectively, and the third direction D3 may be a vertical direction.

When viewed in plan view, the contact region CCR may extend in the first direction D1 from the cell array region CAR. The cell array region CAR may be an area on which are provided vertical channel structures VS and bit lines BL electrically connected to the vertical channel structures VS which will be discussed below. The contact region CCR may be an area on which is provided a stepwise structure including pads portions ELp which will be discussed below. Alternatively, or in addition to, the contact region CCR may extend in the second direction D2 from the cell array region CAR.

The first substrate 10 may be, for example, a silicon substrate, a silicon-germanium substrate, a germanium substrate, or a monocrystalline epitaxial layer grown on a monocrystalline silicon substrate.

A device isolation layer 11 may be provided in the first substrate 10. The device isolation layer 11 may define an active section of the first substrate 10. For example, the device isolation layer 11 may include silicon oxide.

The peripheral circuit structure PS may be provided on the first substrate 10. The peripheral circuit structure PS may include peripheral circuit transistors PTR on the active section of the first substrate 10, peripheral contact plugs 31, peripheral circuit lines 33, and a lower dielectric layer 30. The peripheral circuit lines 33 may be electrically connected through the peripheral contact plugs 31 to the peripheral circuit transistors PTR. The peripheral circuit structure PS may correspond to the first structure 1100F of FIG. 1, and the peripheral circuit lines 33 may correspond to the peripheral wiring lines 3110 of FIGS. 3 and 4.

A peripheral circuit may be constituted (i.e., formed) by the peripheral circuit transistors PTR, the peripheral contact plugs 31, and the peripheral circuit lines 33. For example, the peripheral circuit transistors PTR may constitute the decoder circuit 1110, the page buffer 1120, and the logic circuit 1130 of FIG. 1. Each of the peripheral circuit transistors PTR may be an NMOS transistor or a PMOS transistor. Each of the peripheral circuit transistors PTR may be a planar transistor or a recessed channel transistor (RCT). The peripheral transistors may be high-voltage transistors or low-voltage transistors.

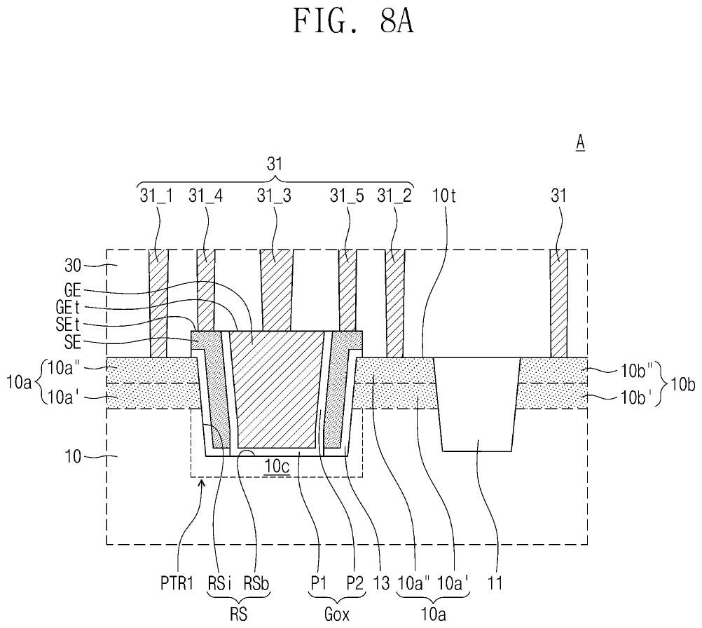

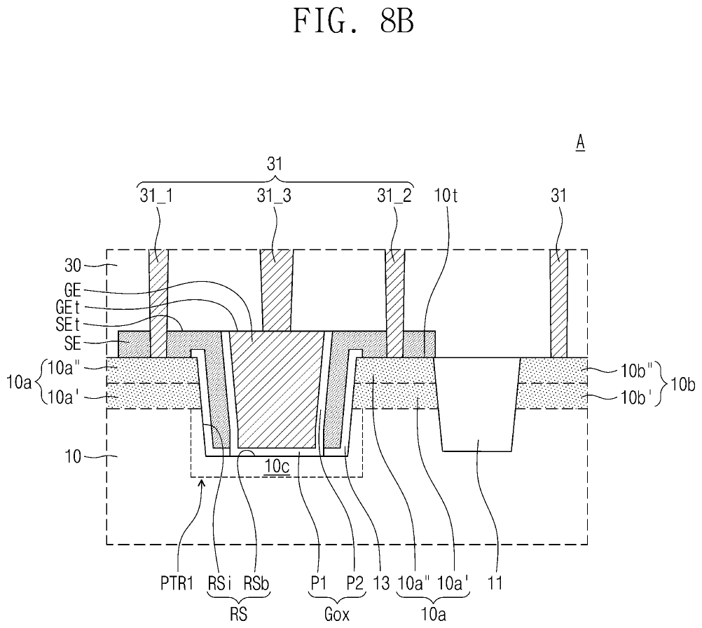

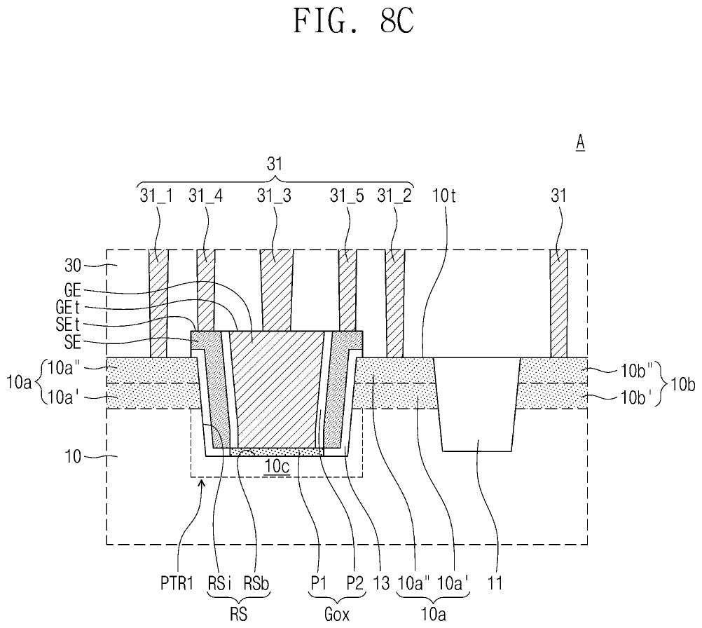

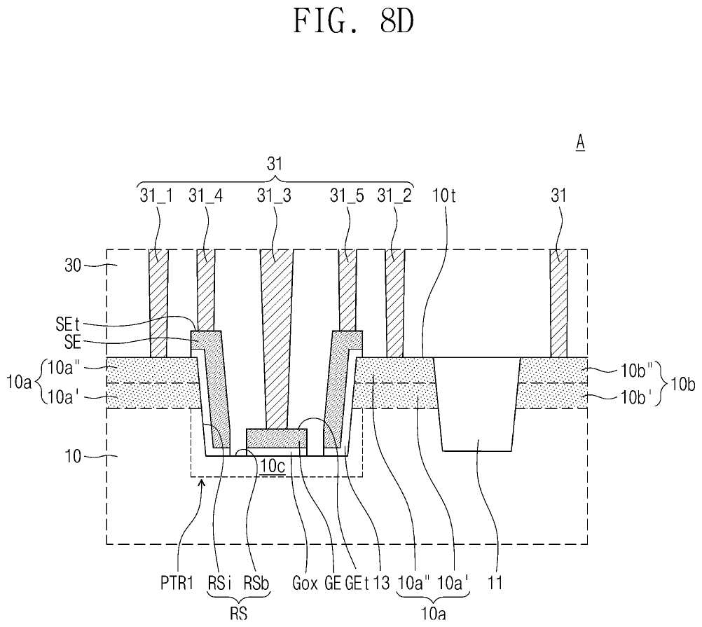

The peripheral circuit transistors PTR may include first peripheral circuit transistors PTR1 and second peripheral circuit transistors PTR2. The first peripheral circuit transistors PTR1 may be provided in the first substrate 10. For example, the first peripheral circuit transistors PTR1 may be recessed channel transistors and high-voltage transistors capable of withstanding high voltages such as program voltages. The first peripheral circuit transistors PTR1 will be further discussed in detail in FIGS. 8A to 8D.

Each of the second peripheral circuit transistors PTR2 may include a second gate dielectric layer 21, a second gate electrode 23, a peripheral capping pattern 25, and a peripheral gate spacer 27. The second gate electrode 23 may be on the first substrate 10, and the second gate dielectric layer 21 may be between the second gate electrode 23 and the first substrate 10. The peripheral capping pattern 25 may be provided on the second gate electrode 23. The peripheral gate spacer 27 may cover sidewalls of the second gate dielectric layer 21, the second gate electrode 23, and the peripheral capping pattern 25. For example, the second peripheral circuit transistors PTR2 may be planar transistors and low-voltage transistors operating at low voltages.

The peripheral circuit lines 33 may be electrically connected through the peripheral contact plugs 31 to the peripheral circuit transistors PTR. For example, the peripheral contact plugs 31 may each have a width in the first direction D1 or the second direction D2, and the width may increase with increasing distance in the third direction D3 from the first substrate 10. The peripheral contact plugs 31 and the peripheral circuit lines 33 may include a conductive material, such as metal.

The lower dielectric layer 30 may be provided on the top surface of the first substrate 10. On the first substrate 10, the lower dielectric layer 30 may cover the peripheral circuit transistors PTR, the peripheral contact plugs 31, and the peripheral circuit lines 33. The lower dielectric layer 30 may include a plurality of dielectric layers stacked in the third direction D3 to form a multi-layered structure. For example, each of the plurality of dielectric layers may include one or more of silicon oxide, silicon nitride, silicon oxynitride, and low-k (low-dielectric constant) dielectric materials.

The lower dielectric layer 30 may be provided thereon with the cell array structure CS that includes a second substrate 100 and a stack structure ST on the second substrate 100. The second substrate 100 may extend in the first and second directions D1 and D2. The second substrate 100 may not be provided on a partial area of the contact region CCR; that is, the second substrate 100 may not extend entirely across the contact region CCR in the first direction D1. The second substrate 100 may be a semiconductor substrate including a semiconductor material. The second substrate 100 may include, for example, at least one material selected from silicon (Si), germanium (Ge), silicon germanium (SiGe), gallium arsenic (GaAs), indium gallium arsenic (InGaAs), aluminum gallium arsenic (AlGaAs), and a combination thereof.

The stack structure ST may be provided on the second substrate 100. The stack structure ST may extend from the cell array region CAR toward the contact region CCR. The stack structure ST may correspond to the gate stack structures 3210 of FIGS. 3 and 4. The stack structure ST may be provided in plural, and the plurality of stack structures ST may be arranged along the second direction D2 and spaced apart in the second direction D2 from each other across a first separation structure SS1 which will be discussed below. For convenience of description, the following explanation will focus on a single stack structure ST, but this explanation may also be applicable to other stack structures ST.

The stack structure ST may include interlayer dielectric layers ILDa and ILDb and electrodes ELa and ELb that are alternately stacked in the third direction D3. The electrodes ELa and ELb may correspond to the first and second gate lower lines LL1 and LL2, the first and second gate upper lines UL1 and UL2, and the word lines WL of FIG. 1.

The stack structure ST may include a first stack structure ST1 on the second substrate 100 and a second stack structure ST2 on the first stack structure ST1. The first stack structure ST1 may include first interlayer dielectric layers ILDa and first electrodes ELa that are alternately stacked in the third direction D3, and the second stack structure ST2 may include second interlayer dielectric layers ILDb and second electrodes ELb that are alternately stacked in the third direction D3. The first and second electrodes ELa and ELb may have substantially the same thickness in the third direction D3.

The first and second electrodes ELa and ELb may have respective lengths in the first direction D1 that decrease with increasing distance in the third direction D3 from the second substrate 100. For example, each of the first and second electrodes ELa and ELb may have a length in the first direction D1 that is greater than a length in the first direction D1 of an immediately overlying electrode. A lowermost one of the first electrodes ELa in the first stack structure ST1 may have a maximum length in the first direction D1 relative to the other first electrodes ELa in the first stack structure ST1, and an uppermost one of the second electrodes ELb in the second stack structure ST2 may have a minimum length in the first direction D1 relative to the other second electrodes ELb in the second stack structure ST2.

The first and second electrodes ELa and ELb may have their pad portions ELp on the contact region CCR. The pad portions ELp of the first and second electrodes ELa and ELb may be located at their positions that are horizontally and vertically different from each other. The pad portions ELp may constitute a stepwise structure along the first direction D1.

The stepwise structure may be arranged such that each of the first and second stack structures ST1 and ST2 may have a thickness in the third direction D3 which decreases with increasing distance in the first direction D1 from an outermost one of vertical channel structures VS which will be discussed below, and such that the first and second electrodes ELa and ELb may have their sidewalls spaced apart at a regular interval from each other along the first direction D1 when viewed in plan view. For example, the first and second electrodes ELa and ELb may include at least one material selected from doped semiconductors (e.g., doped silicon), metals (e.g., tungsten, copper, or aluminum), conductive metal nitrides (e.g., titanium nitride or tantalum nitride), and transition metals (e.g., titanium or tantalum), or may include tungsten.

The first and second interlayer dielectric layers ILDa and ILDb may be provided between adjacent pairs of the first and second electrodes ELa and ELb, and each of the first and second interlayer dielectric layers ILDa and ILDb may have a sidewall aligned with that of an underlying one of the first and second electrodes ELa and ELb. Likewise the first and second electrodes ELa and ELb, the first and second interlayer dielectric layers ILDa and ILDb may have their lengths in the first direction D1 that decrease with increasing distance in the third direction D3 from the second substrate 100.

A lowermost one of the second interlayer dielectric layers ILDb may be in contact with an uppermost one of the first interlayer dielectric layers ILDa. Each of the first and second interlayer dielectric layers ILDa and ILDb may have a thickness in the third direction D3 that is less than that of each of the first and second electrodes ELa and ELb. A lowermost one of the first interlayer dielectric layers ILDa may have a thickness in the third direction D3 that is less than that of each of the other first and second interlayer dielectric layers ILDa and ILDb. An uppermost one of the second interlayer dielectric layers ILDb may have a thickness in the third direction D3 that is greater than that of each of the other first and second interlayer dielectric layers ILDa and ILDb.

Except the lowermost first interlayer dielectric layer ILDa and the uppermost second interlayer dielectric layer ILDb, other first and second interlayer dielectric layers ILDa and ILDb may have substantially the same thickness in the third direction D3. The present inventive concepts, however, are not limited thereto. The first and second interlayer dielectric layers ILDa and ILDb may have their thicknesses in the third direction D3 that are changed depending on properties of a semiconductor device.

The first and second interlayer dielectric layers ILDa and ILDb may include one or more of silicon oxide, silicon nitride, silicon oxynitride, low-k dielectric materials, high-density plasma (HDP) oxide, and tetraethylorthosilicate (TEOS).

A source structure SCP may be provided between the second substrate 100 and the stack structure ST on the cell array region CAR. The source structure SCP may correspond to the common source line CSL of FIG. 1 and/or the common source line 3205 of FIGS. 3 and 4. The source structure SCP may include a first source conductive pattern SCP1 and a second source conductive pattern SCP2 that are sequentially stacked on the second substrate 100 in the third direction D3. The second source conductive pattern SCP2 may be provided between the first source conductive pattern SCP1 and the lowermost first interlayer dielectric layer ILDa. The first source conductive pattern SCP1 may have a thickness in the third direction D3 that is greater than that of the second source conductive pattern SCP2. The first and second source conductive patterns SCP1 and SCP2 may include either a semiconductor material such as silicon or a semiconductor material doped with impurities. When the first and second source conductive patterns SCP1 and SCP2 include an impurity-doped semiconductor material, the first source conductive pattern SCP1 may have an impurity concentration greater than that of the second source conductive pattern SCP2.

The first source conductive pattern SCP1 of the source structure SCP may be provided only on the cell array region CAR, but not on the contact region CCR. The second source conductive pattern SCP2 of the source structure SCP may extend in the first direction D1 from the cell array region CAR at least partially into the contact region CCR.

First, second, and third buffer dielectric layers 111, 113, and 115 may be provided between the lowermost one of the first interlayer dielectric layers ILDa and the second substrate 100 on the contact region CCR. The first, second, and third buffer dielectric layers 111, 113, and 115 may be sequentially stacked on the second substrate 100 in the third direction D3. The second buffer dielectric layer 113 may include a dielectric material different from that of the first and third buffer dielectric layers 111 and 115. The second buffer dielectric layer 113 may be thicker than the first and third buffer dielectric layers 111 and 115, but the present inventive concepts are not limited thereto. The first, second, and third buffer dielectric layers 111, 113, and 115 may include, for example, at least one selected from silicon oxide, silicon nitride, silicon oxynitride, silicon carbide, and silicon-germanium.

On the cell array region CAR, a plurality of vertical channel structures VS may be provided to extend into the stack structure ST and the source structure SCP. The vertical channel structures VS may extend into at least a portion of the second substrate 100, and each of the vertical channel structures VS may have a bottom surface at a level lower than that of a top surface of the second substrate 100 and that of a bottom surface of the source structure SCP. For example, the vertical channel structures VS may be in direct contact with the second substrate 100.

When viewed in plan view, the vertical channel structures VS may be arranged in a zigzag (i.e., staggered) fashion in the first direction D1 or the second direction D2. The vertical channel structures VS may not be provided on the contact region CCR. The vertical channel structures VS may correspond to the vertical channel structures 3220 of FIGS. 2 to 4. The vertical channel structures VS may correspond to channels of the lower transistors LT1 and LT2, the upper transistors UT1 and UT2, and the memory cell transistors MCT depicted in FIG. 1.

The vertical channel structures VS may be provided in vertical channel holes CH that extend in the third direction D3 into the stack structure ST. Each of the vertical channel holes CH may include a first vertical channel hole CH1 that penetrates the first stack structure ST1 and a second vertical channel hole CH2 that penetrates the second stack structure ST2. The first and second vertical channel holes CH1 and CH2 of each of the vertical channel holes CH may be connected to each other in the third direction D3.

Each of the vertical channel structures VS may include a first vertical channel structure VSa and a second vertical channel structure VSb. The first vertical channel structure VSa may be provided in the first vertical channel hole CH1, and the second vertical channel structure VSb may be provided in the second vertical channel hole CH2. The second vertical channel structure VSb may be provided on the first vertical channel structure VSa, and the first vertical channel structure VSa and the second vertical channel structure VSb may be connected to each other in the third direction D3.

Each of the first and second vertical channel structures VSa and VSb may have a width in the first direction D1 or the second direction D2, and the width may increase with increasing distance from the upper surface of the second substrate 100 in the third direction D3. A width at an uppermost portion of the first vertical channel structure VSa may be greater than a width at a lowermost portion of the second vertical channel structure VSb. For example, each of the vertical channel structures VS may have a sidewall that has a step difference at a boundary between the first vertical channel structure VSa and the second vertical channel structure VSb. The present inventive concepts, however, are not limited thereto, and each of the vertical channel structures VS may have a sidewall that either has three or more step differences at different levels or is flat with no step difference.

On the contact region CCR, an intermediate dielectric layer 120 may be provided over the stack structure ST and a portion of the lower dielectric layer 30. The intermediate dielectric layer 120 may be provided on the pad portions ELp of the first and second electrodes ELa and ELb, while covering the stepwise structure of the stack structure ST. The intermediate dielectric layer 120 may have a substantially flat (i.e., planar) top surface. The top surface of the intermediate dielectric layer 120 may be substantially coplanar with that of the stack structure ST. For example, the top surface of the intermediate dielectric layer 120 may be substantially coplanar with that the uppermost one of the second interlayer dielectric layers ILDb in the stack structure ST.

The intermediate dielectric layer 120 may include one dielectric layer or a plurality of stacked dielectric layers. The intermediate dielectric layer 120 may include a dielectric material, such as one or more of silicon oxide, silicon nitride, silicon oxynitride, and low-k dielectric materials. The intermediate dielectric layer 120 may include a different dielectric material from that of the first and second interlayer dielectric layers ILDa and ILDb. For example, when the first and second interlayer dielectric layers ILDa and ILDb of the stack structure ST include high-density plasma oxide, the intermediate dielectric layer 120 may include tetraethylorthosilicate (TEOS).

Dummy vertical channel structures DVS may be provided around cell contact plugs CCP which will be discussed. The dummy vertical channel structures DVS may not be provided on the cell array region CAR. The dummy vertical channel structures DVS and the vertical channel structures VS may be formed simultaneously with each other and may have substantially the same structure. For example, on the contact region CCR, the dummy vertical channel structures DVS may extend into the intermediate dielectric layer 120 and the stack structure ST. Alternatively, the vertical channel structures VS and the dummy vertical channel structures DVS may not be formed simultaneously with each other, or the dummy vertical channel structures DVS may not be provided.

A first dielectric layer 130 may be provided on the stack structure ST and the intermediate dielectric layer 120, and a second dielectric layer 140 may be provided on the first dielectric layer 130.

Cell contact plugs CCP may be provided to extend into the intermediate dielectric layer 120 and the first dielectric layer 130 to come into contact with the first and second electrodes ELa and ELb. Each of the cell contact plugs CCP may penetrate one of the first and second interlayer dielectric layers ILDa and ILDb to directly contact one of the pad portions ELp of the first and second electrodes ELa and ELb. The cell contact plugs CCP may correspond to the gate connection lines 3235 of FIGS. 3 and 4.

Each of the cell contact plugs CCP may be spaced apart in a horizontal direction and electrically separated from the first and second electrodes ELa and ELb below the pad portions ELp across a first plug dielectric pattern IP1, which horizontal direction is one direction on a plane parallel to the first direction D1 and the second direction D2. Each of the cell contact plugs CCP may be spaced apart in the horizontal direction and electrically separated from the second substrate 100 across a second plug dielectric pattern IP2 formed in the second substrate 100. The first and second plug dielectric patterns IP1 and IP2 may include the same material as that of the first and second interlayer dielectric layers ILDa and ILDb of the stack structure ST. Each of the cell contact plugs CCP may have a bottom surface located at a level lower than that of the bottom surface of the second substrate 100 in the third direction D3. A height in the third direction D3 of each of the cell contact plugs CCP may be substantially the same as a height in the third direction D3 of a peripheral contact plug TCP which will be discussed below; that is, a top surface of the peripheral contact plug TCP and a top surface of each of the cell contact plugs CCP may be vertically coplanar.

The peripheral contact plug TCP may be provided to extend into the intermediate dielectric layer 120 and at least a portion of the lower dielectric layer 30 to come into electrical connection with the peripheral circuit transistors PTR of the peripheral circuit structure PS. More than one peripheral contact plug TCP may be provided. The peripheral contact plug TCP may be spaced apart in the first direction D1 from the second substrate 100, the source structure SCP, and the stack structure ST. The peripheral contact plug TCP may correspond to the through wiring line 3245 of FIG. 3.

The cell contact plugs CCP and the peripheral contact plug TCP may include a conductive pattern including at least one metal selected from aluminum, copper, tungsten, molybdenum, and cobalt, and may also include a barrier pattern including a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

When a plurality of stack structures ST are provided, a first separation structure SS1 may be provided to extend in the first direction D1 between the plurality of stack structures ST. The first separation structure SS1 may extend along the first direction D1 from the cell array region CAR to the contact region CCR of the first substrate 10. The first separation structure SS1 may be spaced apart in the second direction D2 from the vertical channel structures VS. The first separation structure SS1 may have a top surface located at the same level as (i.e., coplanar with) that of top surfaces of the vertical channel structures VS. The first separation structure SS1 may have a bottom surface located at substantially the same level as that of a bottom surface of the first source conductive pattern SCP1. The first separation structure SS1 may penetrate in the third direction D3 through the stack structure ST. The first separation structure SS1 may be provided in plural, and the stack structure ST may be positioned between the plurality of first separation structures SS1. For example, the first separation structure SS1 may include a dielectric material, such as one or more of silicon oxide, silicon nitride, and silicon oxynitride.

A second separation structure SS2 may be provided between a plurality of first separation structures SS1 that are adjacent to each other in the second direction D2. When viewed in plan view, the second separation structure SS2 may be between the first separation structures SS1 and may overlap some of the vertical channel structures VS. The term “overlap” (or “overlapping,” or like terms), as used herein, is intended to broadly refer to a first element that intersects with at least a portion of a second element in the vertical direction (i.e., the third direction D3), but does not require that the first and second elements be completely aligned with one another in a horizontal plane (i.e., in the first direction D1 and/or the second direction D2). The second separation structure SS2 may extend in the first direction D1. The second separation structure SS2 may penetrate an uppermost one of the electrodes ELa and ELb and an uppermost one of the interlayer dielectric layers ILDa and ILDb of the stack structure ST. The second separation structure SS2 may serve to separate a string selection line of a semiconductor device. For example, the second separation structure SS2 may include a dielectric material, such as one or more of silicon oxide, silicon nitride, and silicon oxynitride.

The second dielectric layer 140 may be provided thereon with bit lines BL and conductive lines CL. The bit lines BL may extend in the second direction D2 and may be spaced apart from each other in the first direction D1. The bit lines BL may correspond to the bit lines BL of FIG. 1 and/or the bit lines 3240 of FIGS. 3 and 4. The conductive lines CL may extend in the second direction D2 and may be spaced apart from each other in the first direction D1. The conductive lines CL may correspond to the conductive lines 3250 of FIGS. 3 and 4.

On the cell array region CAR, bit-line contact plugs BLCP may be provided to extend through and located in the first and second dielectric layers 130 and 140. The bit-line contact plugs BLCP may be positioned between and electrically connect corresponding vertical channel structures VS and corresponding bit lines BL.

On the contact region CCR, conductive-line contact plugs CLCP may be provided to extend through and located in the second dielectric layer 140. The conductive-line contact plugs CLCP may be positioned between and electrically connect corresponding conductive lines CL and corresponding cell contact plugs CCP or corresponding peripheral contact plugs TCP. The bit-line contact plugs BLCP and the conductive-line contact plugs CLCP may include a metallic material, such as tungsten.

FIGS. 8A to 8D illustrate enlarged views of section A depicted in FIG. 6, partially showing a semiconductor device according to some embodiments of the present inventive concepts.

Referring to FIG. 8A, the first substrate 10 may have a recess region RS obtained by removing a portion of the first substrate 10. The recess region RS may have a bottom surface RSb and inner sidewalls RSi. The bottom surface RSb of the recess region RS may be positioned between the inner sidewalls RSi of the recess region RS, and may be located at a level lower than that of a top surface 10t of the first substrate 10 in the third direction D3. The first substrate 10 may include impurities having a first conductivity type (e.g., n-type) or second conductivity type (e.g., p-type).

The first substrate 10 may be provided therein with first impurity regions 10a on opposite sides of the recess region RS and extending in the horizontal direction. The first impurity regions 10a may be adjacent to the top surface 10t of the first substrate 10, and may be located at a level higher than that of the bottom surface RSb of the recess region RS in the third direction D3. The first impurity regions 10a may be areas into which are doped impurities whose conductivity type is opposite to that the first substrate 10. When the first substrate 10 includes impurities having a second conductivity type opposite in polarity to the first conductivity type, the first impurity regions 10a may include impurities having a first conductivity type. When the first substrate 10 includes impurities having a first conductivity type, the first impurity regions 10a may include impurities having a second conductivity type.

Each of the first impurity regions 10a may include an upper impurity region 10a″ and a lower impurity region 10a′. The upper impurity region 10a″ may be positioned on the lower impurity region 10a′. The upper impurity region 10a″ may have an impurity concentration greater than that of the lower impurity region 10a′. For example, the lower impurity region 10a′ may correspond to a lightly doped drain of the first peripheral circuit transistor PTR1, and the upper impurity region 10a″ may correspond to a source/drain region of the first peripheral circuit transistor PTR1.

A channel region 10c may be below the bottom surface RSb of the recess region RS and may be provided in the first substrate 10. The channel region 10c may extend from below the bottom surface RSb of the recess region RS to the first impurity regions 10a, while being adjacent to the inner sidewalls RSi of the recess region RS. For example, the channel region 10c may have a U shape extending along the bottom surface RSb and at least a portion of the inner sidewalls RSi of the recess region RS. As the channel region 10c includes impurities having the same conductivity type as that of the first substrate 10, the channel region 10c may have a different conductivity type from that of the first impurity region 10a. The channel region 10c may correspond to a channel of the first peripheral circuit transistor PTR1. For example, the channel region 10c may be a path along which carries move between the first impurity regions 10a positioned on opposite sides of the recess region RS.

The first substrate 10 may be provided therein with a second impurity region 10b spaced apart in a horizontal direction from the first impurity region 10a across a device isolation layer 11. The second impurity region 10b may be located at the same vertical level as that of the first impurity region 10a. The second impurity region 10b may include impurities having the same conductivity type as that of the first substrate 10 and the channel region 10c. For example, the second impurity region 10b may have a different conductivity type from that of the first impurity regions 10a. The second impurity region 10b may include an upper impurity region 10b″ and a lower impurity region 10b′. The upper impurity region 10b″ may be positioned on the lower impurity region 10b′. The upper impurity region 10b″ may, in some embodiments, have an impurity concentration greater than that of the lower impurity region 10b′.

The first peripheral circuit transistor PTR1 may include a first gate electrode GE, a first gate dielectric layer Gox, shield electrodes SE, and dielectric patterns 13. The first peripheral circuit transistor PTR1 may be provided in the recess region RS of the first substrate 10. The first impurity regions 10a may be positioned on opposite sides of the first gate electrode GE, opposite sides of the first gate dielectric layer Gox, opposite sides of the shield electrodes SE, and opposite sides of the dielectric patterns 13.

The first gate electrode GE may be positioned on the bottom surface RSb of the recess region RS and disposed on a center of the recess region RS in the first substrate 10. The first gate electrode GE may be horizontally spaced apart from the first impurity regions 10a. The first gate electrode GE may extend in a vertical direction, and may have a top surface GEt located at a vertical level higher than that of the top surface 10t of the first substrate 10. Therefore, the first gate electrode GE may horizontally overlap the first impurity regions 10a. The first gate electrode GE may have a horizontal (i.e., lateral) width that increases with increasing vertical distance from a bottom surface of the first gate electrode GE to the top surface GEt of the first gate electrode GE. For example, the width of the first gate electrode GE may have a minimum value at the bottom surface thereof and a maximum value at the top surface GEt thereof. The first gate electrode GE may include, for example, at least one selected from doped semiconductors (e.g., doped silicon), metals (e.g., tungsten, copper, or aluminum), conductive metal nitrides (e.g., titanium nitride or tantalum nitride), and transition metals (e.g., titanium or tantalum).

A pair of shield electrodes SE may be provided on opposite sides of the first gate electrode GE. The shield electrodes SE may be positioned on the inner sidewalls RSi of the recess region RS, and may be disposed between the first gate electrode GE and the inner sidewalls RSi of the recess region RS. The shield electrodes SE may have shapes that extend along the inner sidewalls RSi of the recess region RS. The shield electrodes SE may have top surfaces SEt located at a vertical level higher than that of the top surface 10t of the first substrate 10. The top surfaces SEt of the shield electrodes SE may be coplanar with the top surface GEt of the first gate electrode GE. Each of the shield electrodes SE may have a horizontal width less than that of the first gate electrode GE. For example, the horizontal width of the shield electrode SE may be about half the horizontal width of the first gate electrode GE. The shield electrodes SE may include, for example, at least one material selected from doped semiconductors (e.g., doped silicon), metals (e.g., tungsten, copper, or aluminum), conductive metal nitrides (e.g., titanium nitride or tantalum nitride), and transition metals (e.g., titanium or tantalum).

The first gate dielectric layer Gox may be provided below the first gate electrode GE, and may be positioned between the first gate electrode GE and the bottom surface RSb of the recess region RS. The first gate dielectric layer Gox may include a first portion P1 extending horizontally across a portion of the bottom surface RSb of the recess region RS, and second portions P2 extending vertically along sidewalls of the first gate electrode GE. The second portions P2 may be connected to opposite ends of the first portion P1. For example, the first portion P1 may be positioned between the second portions P2. The first portion P1 may be positioned between the first gate electrode GE and the channel region 10c, and may cover the bottom surface RSb of the recess region RS. The second portions P2 may be positioned between the first gate electrode GE and the shield electrodes SE, and may extend in a vertical direction. The second portions P2 of the first gate dielectric layer Gox may electrically insulate the first gate electrode GE from the shield electrodes SE. The first gate dielectric layer Gox may have a constant thickness. The thickness of the first gate dielectric layer Gox may be less than the horizontal width of each of the shield electrodes SE. The first gate dielectric layer Gox may include, for example, one or more of silicon oxide, silicon nitride, silicon oxynitride, and low-k dielectric materials.

The dielectric patterns 13 may be provided on the inner sidewalls RSi of the recess region RS, and may be positioned between the shield electrodes SE and the inner sidewalls RSi of the recess region RS. The dielectric patterns 13 may cover the inner sidewalls RSi and a portion of the bottom surface RSb of the recess region RS. The dielectric patterns 13 covering a portion of the bottom surface RSb of the recess region RS may be in contact with the first portion P1 of the first gate dielectric layer Gox. The dielectric patterns 13 may electrically insulate the shield electrodes SE from the first substrate 10. The dielectric pattern 13 may have a constant thickness, and the thickness of the dielectric pattern 13 may be substantially the same as that of the first gate dielectric layer Gox. The dielectric patterns 13 may include, for example, one or more of silicon oxide, silicon nitride, and silicon oxynitride.

The peripheral contact plugs 31 may extend vertically into the lower dielectric layer 30 to come into connection with the first gate electrode GE, the shield electrodes SE, the first impurity regions 10a, and the second impurity region 10b. For example, the peripheral contact plugs 31 may include first, second, third, fourth, and fifth plugs 31_1, 31_2, 31_3, 31_4, and 31_5, respectively. The first and second plugs 31_1 and 31_2 may be connected to the first impurity regions 10a. The third plug 31_3 may be connected to the first gate electrode GE. The fourth and fifth plugs 31_4 and 31_5 may be connected to the shield electrodes SE. It may thus be possible to independently control a voltage applied to each of the first gate electrode GE, the shield electrodes SE, and the first impurity regions 10a.

Referring to FIG. 8B, the shield electrodes SE may extend from the inner sidewalls RSi of the recess region RS horizontally onto the top surface 10t of the first substrate 10, thereby covering at least a portion of the top surface 10t of the first substrate 10. Portions of the shield electrodes SE may be in contact with the upper impurity regions 10a″ of the first impurity regions 10a. The first and second plugs 31_1 and 31_2 may extend vertically into the lower dielectric layer 30 and the shield electrodes SE to contact the upper impurity regions 10a″ of the first impurity regions 10a. As one peripheral contact plug 31 is shared by the first impurity regions 10a and the shield electrodes SE positioned on the first impurity regions 10a, the fourth and fifth plugs 31_4 and 31_5 of FIG. 8A may be omitted.

Referring to FIG. 8C, the first portion P1 and the second portions P2 of the first gate dielectric layer Gox may include different materials from each other. The second portions P2 may include a material whose dielectric constant is less than that of the first portion P1. For example, the first portion P1 may include one or more of silicon oxide, silicon nitride, and silicon oxynitride, and the second portions P2 may include a low-k dielectric material or an air gap. When the second portions P2 include an air gap, an etching process having an etch selectivity may be used to remove the second portions P2 of the first gate dielectric layer Gox and the lower dielectric layer 30 may be deposited to form the air gap.

A material whose dielectric constant is low may be provided between the first gate electrode GE and the shield electrodes SE, and thus there may be a reduction in electrical capacitance between the first gate electrode GE and the shield electrodes SE. Therefore, the first peripheral circuit transistor PTR1 may increase in operating speed.

Referring to FIG. 8D, the first gate electrode GE and the shield electrodes SE may include the same material as each other. The first gate electrode GE may have a thickness in a direction perpendicular to the bottom surface RSb of the recess region RS, and the shield electrode SE may have a thickness in a direction perpendicular to the inner sidewall RSi of the recess region RS. The thickness of the first gate electrode GE may be substantially the same as the thickness of the shield electrode SE. Thus, the top surface GEt of the first gate electrode GE may be located at a vertical level lower than that of the top surface 10t of the first substrate 10. For example, one layer may be formed into the first gate electrode GE and the shield electrodes SE. It may therefore be possible to simplify a method of fabricating a semiconductor device.

A portion of the lower dielectric layer 30 may be positioned between the first gate electrode GE and the shield electrodes SE. Thus, the first gate dielectric layer Gox may be provided between the first gate electrode GE and the bottom surface RSb of the recess region RS, and the second portions P2 of FIGS. 8A to 8C may be omitted.

Referring to FIGS. 8A to 8D, the first peripheral circuit transistor PTR1 of the present inventive concepts may include shield electrodes SE between the first gate electrode GE and the first impurity regions 10a.

According to an embodiment, a ground voltage or a zero-volt voltage may be applied to the first plug 31_1. A gate voltage may be applied to the third, fourth, and fifth plugs 31_3, 31_4, and 31_5. A program voltage may be applied to the second plug 31_2. For example, the gate voltage may be about 28 V, and the program voltage may be about 24 V. A body bias may be applied to the peripheral contact plug 31 connected to the second impurity region 10b. In this case, the first peripheral circuit transistor PTR1 may be turned on. For example, the gate electrode GE and the shield electrodes SE may serve as a gate of the first peripheral circuit transistor PTR1, and carriers may move through the channel region 10c of the first substrate 10.

According to an embodiment, a ground voltage or a zero-volt voltage may be applied to the first plug 31_1. A gate voltage may be applied to the third and fourth plugs 31_3 and 31_4. A program voltage may be applied to the second and fifth plugs 31_2 and 31_5. For example, the gate voltage may be about 0 V, and the program voltage may be about 24 V. In this case, the first peripheral circuit transistor PTR1 may be turned off. For example, carriers may not move through the channel region 10c of the first substrate 10. The shield electrode SE connected to the fifth plug 31_5 may block a leakage current from occurring between the first gate electrode GE and the first impurity region 10a connected to the second plug 31_2.

The shield electrodes SE may serve as a gate of the first peripheral circuit transistor PTR1 to increase a channel length of the first peripheral circuit transistor PTR1, or may block a leakage current from occurring between the first gate electrode GE and the first impurity region 10a to thereby prevent a gate-induced drain leakage (GIDL) phenomenon. Accordingly, a semiconductor device having improved electrical properties may be provided.

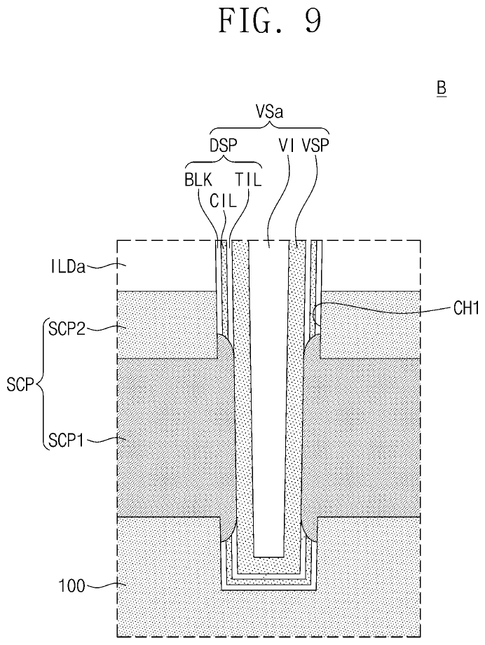

FIG. 9 is a cross-sectional view illustrating an enlarged view of section B depicted in FIG. 6, partially showing a semiconductor device according to some embodiments of the present inventive concepts.

Referring to FIG. 9, the first vertical channel structures VSa may include a data storage pattern DSP, a buried dielectric pattern VI, and a vertical semiconductor pattern VSP.

The data storage pattern DSP may include a blocking dielectric layer BLK, a charge storage layer CIL, and a tunneling dielectric layer TIL that are sequentially stacked. The blocking dielectric layer BLK may be adjacent to the first interlayer dielectric layer ILDa, and the tunneling dielectric layer TIL may be adjacent to the vertical semiconductor pattern VSP. The charge storage layer CIL may be positioned between the blocking dielectric layer BLK and the tunneling dielectric layer TIL. The blocking dielectric layer BLK may cover an inner sidewall and bottom of the first vertical channel hole CH1.

The second vertical channel structure VSb of FIGS. 6 and 7 may have a structure substantially the same as that of the first vertical channel structure VSa. For example, the second vertical channel structure VSb may include a data storage pattern, a buried dielectric pattern, and a vertical semiconductor pattern, and the data storage pattern may include a blocking dielectric layer, a charge storage layer, and a tunneling dielectric layer that are sequentially stacked.

The first source conductive pattern SCP1 of the source structure SCP may be in contact with the vertical semiconductor pattern VSP, and the second source conductive pattern SCP2 of the source structure SCP may be spaced apart horizontally from the vertical semiconductor pattern VSP by the data storage pattern DSP; that is, the data storage pattern DSP laterally separates the second source conductive pattern SCP2 from the vertical semiconductor pattern VSP. The first source conductive pattern SCP1 may be spaced apart horizontally from the buried dielectric pattern VI by the vertical semiconductor pattern VSP; that is, the vertical semiconductor pattern VSP laterally separates the first source conductive pattern SCP1 from the buried dielectric pattern VI. The first source conductive pattern SCP1 may include a protrusion located at a level higher than that of a bottom surface of the second source conductive pattern SCP2 and a protrusion located at a level lower than that of a bottom surface of the first source conductive pattern SCP1 relative to the top surface of the second substrate 100. The protrusions of the first source conductive pattern SCP1 may be located at a level lower than that of a top surface of the second source conductive pattern SCP2. For example, the protrusions may have curved shapes at surfaces in contact with the data storage pattern DSP.

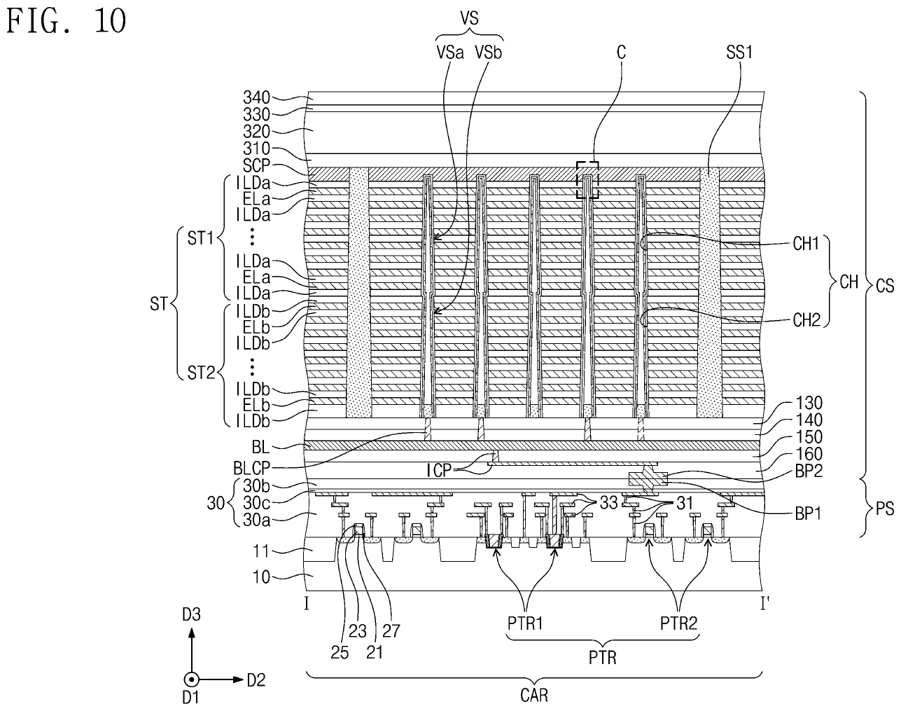

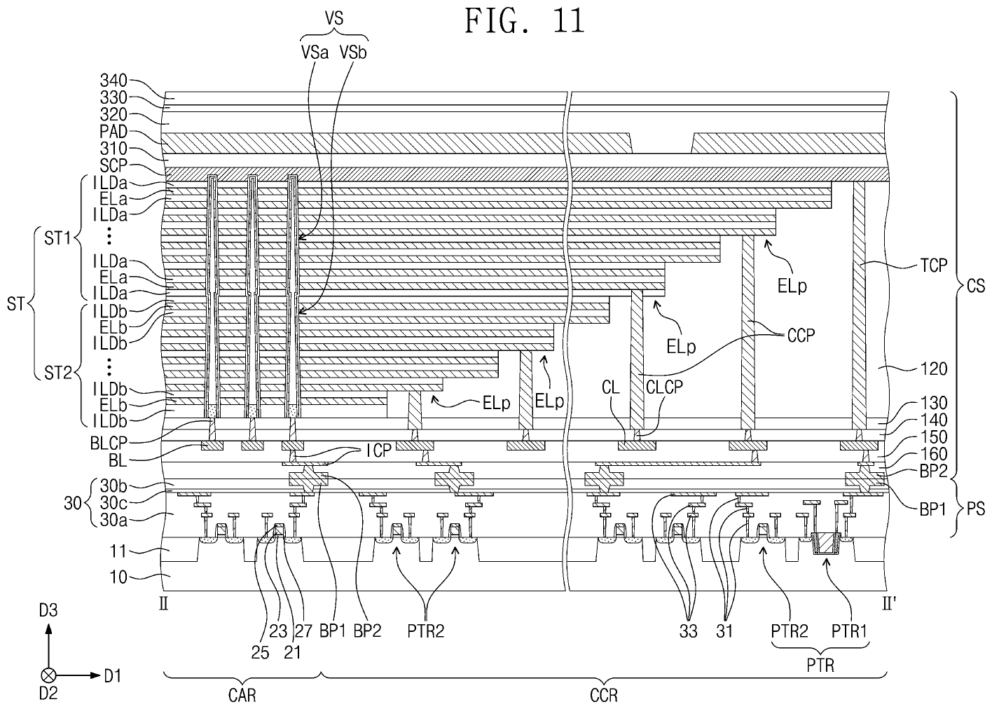

FIGS. 10 and 11 illustrate cross-sectional views respectively taken along lines I-I′ and II-II′ of FIG. 5, showing a semiconductor device according to some embodiments of the present inventive concepts.

For convenience of description, the same components discussed with reference to FIGS. 5 to 7 will be omitted, and a difference thereof will be explained in detail.

Referring to FIGS. 5, 10, and 11, a semiconductor device may include a first substrate 10 including a cell array region CAR and a contact region CCR, a peripheral circuit structure PS on the first substrate 10, and a cell array structure CS on the peripheral circuit structure PS.

As the cell array structure CS is bonded onto the peripheral circuit structure PS, it may be possible to increase a cell capacity per unit area of a semiconductor device. In addition, as the peripheral circuit structure PS and the cell array structure CS are manufactured separately and then bonded to each other, the peripheral transistors PTR may be prevented from being damaged due to various heat treatment processes used during the fabrication of a semiconductor device, and accordingly, it may be possible to improve reliability and electrical properties of the semiconductor device.

The peripheral circuit structure PS may be integrated on a top surface of the first substrate 10, and may include peripheral circuit transistors PTR, peripheral contact plugs 31, peripheral circuit lines 33, first bonding pads BP1, and a lower dielectric layer 30 that surrounds the peripheral circuit transistors PTR, the peripheral contact plugs 31, the peripheral circuit lines 33, and the first bonding pads BP1. The term “surrounds” (or “surround” or like terms) as may be used herein is intended to broadly refer to an element, structure or layer that extends around, envelops, encircles, or encloses another element, structure or layer on all sides, although breaks or gaps may also be present. The first bonding pads BP1 may be electrically connected to the peripheral circuit transistors PTR through the peripheral contact plugs 31 and the peripheral circuit lines 33.

The peripheral circuit transistors PTR may include a first peripheral circuit transistor PTR1 and a second peripheral circuit transistor PTR2. The first peripheral circuit transistor PTR1 and the second peripheral circuit transistor PTR2 may be substantially the same as that discussed with reference to FIGS. 5 to 8D.

The lower dielectric layer 30 may include a first lower dielectric layer 30a, a second lower dielectric layer 30b, and an etch stop layer 30c between the first and second lower dielectric layers 30a and 30b. The etch stop layer 30c may include a dielectric material different from those of the first and second lower dielectric layers 30a and 30b, and may cover a top surface of an uppermost one of the peripheral circuit lines 33.

The first bonding pads BP1 may be disposed in the second lower dielectric layer 30b. The second lower dielectric layer 30b may not cover top surfaces of the first bonding pads BP1; that is, the first bonding pads BP1 may be exposed through the top surface of the second lower dielectric layer 30b. The second lower dielectric layer 30b may have a top surface substantially vertically coplanar with those of the first bonding pads BP1.

The cell array structure CS may be provided on the peripheral circuit structure PS. The cell array structure CS may include a memory cell array including three-dimensionally arranged memory cells. The cell array structure CS may include a source structure SCP, a stack structure ST, vertical channel structures VS, bit lines BL, cell contact plugs CCP, and peripheral contact plugs TCP.

The stack structure ST may include electrodes ELa and ELb and interlayer dielectric layers ILDa and ILDb that are alternately stacked in the third direction D3 (e.g., a vertical direction) perpendicular to the first and second directions D1 and D2.

The electrodes ELa and ELb of the stack structure ST may be stacked to have an inverse stepwise structure on the contact region CCR. For example, the electrodes ELa and ELb may have their lengths in the first direction D1 that increase with increasing distance in the third direction D3 from the peripheral circuit structure PS.

Each of the electrodes ELa and ELb may include a pad portion ELp on the contact region CCR. The pad portions ELp of the electrodes ELa and ELb may be located at positions that are horizontally and vertically different from each other. Cell contact plugs CCP may be correspondingly coupled to the pad portions ELp of the electrodes ELa and ELb.

The stack structure ST may include a first stack structure ST1 and a second stack structure ST2. The first stack structure ST1 may include first interlayer dielectric layers ILDa and first electrodes ELa that are alternately stacked, and the second stack structure ST2 may include second interlayer dielectric layers ILDb and second electrodes ELb that are alternately stacked in the third direction D3.

The second stack structure ST2 may be disposed between the first stack structure ST1 and the peripheral circuit structure PS. For example, the second stack structure ST2 may be provided on a bottom surface of a lowermost one of the first interlayer dielectric layers ILDa in the first stack structure ST1. An uppermost one of the second interlayer dielectric layers ILDb in the second stack structure ST2 may be in contact with the lowermost one of the first interlayer dielectric layers ILDa in the first stack structure ST1.

A lowermost one of the second electrodes ELb in the second stack structure ST2 may have a minimum length in the first direction D1, and an uppermost one of the first electrodes ELa in the first stack structure ST1 may have a maximum length in the first direction D1.

An intermediate dielectric layer 120 may cover the stepwise structured pad portions ELp of the stack structure ST. The intermediate dielectric layer 120 may include one dielectric layer or a plurality of stacked dielectric layers. The intermediate dielectric layer 120 may have substantially flat top and bottom surfaces. The top surface of the intermediate dielectric layer 120 may be substantially vertically coplanar with a top surface of the uppermost one of the first interlayer dielectric layers ILDa in the stack structure ST, and the bottom surface of the intermediate dielectric layer 120 may be substantially coplanar with that of the lowermost one of the second interlayer dielectric layers ILDb in the stack structure ST.

The source structure SCP may be disposed on the uppermost one of the first interlayer dielectric layers ILDa in the first stack structure ST1. The source structure SCP may have a uniform thickness and a substantially flat top surface. The source structure SCP may extend from the cell array region CAR to the contact region CCR. A length in the first direction D1 of the source structure SCP may be greater than a length in the first direction D1 of the uppermost one of the first electrodes ELa in the first stack structure ST1. For example, the source structure SCP may include at least one selected from doped semiconductors (e.g., doped silicon), metals (e.g., tungsten, copper or aluminum), conductive metal nitrides (e.g., titanium nitride or tantalum nitride), and transition metals (e.g., titanium or tantalum).

On the cell array region CAR, the vertical channel structures VS may extend vertically into the stack structure ST to come into contact with the source structure SCP. The vertical channel structures VS may include first vertical channel structures VSa and second vertical channel structures VSb. The first vertical channel structures VSa may be provided in first vertical channel holes CH1 that extend vertically into the first stack structure ST1. The second vertical channel structures VSb may be provided in second vertical channel holes CH2 that extend vertically into the second stack structure ST2.

First, second, third, and fourth dielectric layers 130, 140, 150, and 160, respectively, may be provided between the peripheral circuit structure PS and the stack structure ST and between the peripheral circuit structure PS and the intermediate dielectric layer 120. The first, second, third, and fourth dielectric layers 130, 140, 150, and 160 may be sequentially stacked on the intermediate dielectric layer 120 in the third direction D3. The first dielectric layer 130 may be on bottom surfaces of the vertical channel structures VS. The first, second, third, and fourth dielectric layers 130, 140, 150, and 160 may include one or more of silicon oxide, silicon nitride, silicon oxynitride, and low-k dielectric materials.

The first, second, third, and fourth dielectric layers 130, 140, 150, and 160 may be provided therein with bit lines BL, conductive lines CL, interlayer conductive patterns ICP, and second bonding pads BP2.

The bit lines BL may be positioned on the second dielectric layer 140 on the cell array region CAR, and may extend in the second direction D2 across the stack structure ST. The bit lines BL may be electrically connected through bit-line contact plugs BLCP to the vertical channel structures VS.

The conductive lines CL may be positioned on the second dielectric layer 140 on the contact region CCR, and may extend in the second direction D2. The conductive lines CL may be coupled through conductive-line contact plugs CLCP to the cell contact plugs CCP or the peripheral contact plugs TCP.

The interlayer conductive patterns ICP may be disposed in the third and fourth dielectric layers 150 and 160. On the cell array region CAR, the interlayer conductive patterns ICP may be electrically connected to the bit lines BL. On the contact region CCR, the interlayer conductive patterns ICP may be electrically connected to the conductive lines CL. For example, the interlayer conductive patterns ICP may include at least one material selected from doped semiconductors (e.g., doped silicon), metals (e.g., tungsten, copper, or aluminum), conductive metal nitrides (e.g., titanium nitride or tantalum nitride), and transition metals (e.g., titanium or tantalum).

The second bonding pads BP2 may be provided in the fourth dielectric layer 160. The second bonding pads BP2 may be electrically connected to the interlayer conductive patterns ICP. The second bonding pads BP2 may be formed of, for example, aluminum, copper, or tungsten.

A bottom surface of the second bonding pad BP2 and a top surface of the first bonding pad BP1 may directly contact one another to constitute an intermetallic hybrid bonding. In this description, the term “hybrid bonding” may denote a bonding in which two components of the same kind are merged at an interface therebetween. For example, the bonded first and second bonding pads BP1 and BP2 may have a continuous configuration, such that an invisible interface may be present between the first and second bonding pads BP1 and BP2. The first and second bonding pads BP1 and BP2 may include the same metallic material. For example, the first bonding pad BP1 and the second bonding pad BP2 may be formed into and provided as one integral component.

An upper dielectric layer 310 may be provided on and cover the source structure SCP. Input/output pads PAD may be provided on the upper dielectric layer 310. A capping dielectric layer 320, a protection layer 330, and a passivation layer 340 may be sequentially provided on the upper dielectric layer 310, and the capping dielectric layer 320 may be disposed on the input/output pads PAD.

For example, the capping dielectric layer 320 may include one or more of silicon oxide, silicon nitride, and silicon oxynitride. The protection layer 330 may include one or more of silicon nitride and silicon oxynitride. The passivation layer 340 may include a polyimide material, such as photosensitive polyimide (PSPI).

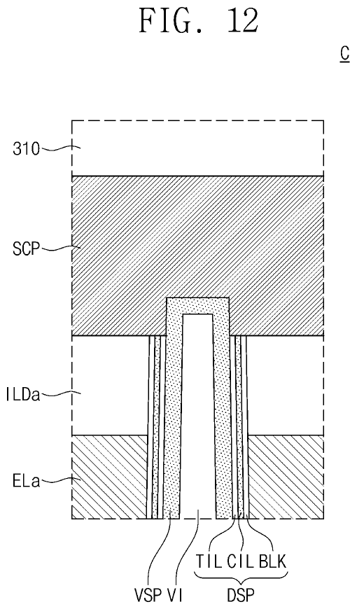

FIG. 12 is a cross-sectional view illustrating an enlarged view of section C depicted in FIG. 10, partially showing a semiconductor device according to some embodiments of the present inventive concepts.

Referring to FIG. 12, the first vertical channel structures VSa (see FIG. 10) may include a data storage pattern DSP, a buried dielectric pattern VI, and a vertical semiconductor pattern VSP. The data storage pattern DSP may include a blocking dielectric layer BLK, a charge storage layer CIL, and a tunneling dielectric layer TIL that are sequentially stacked.

The first vertical channel structure VSa may extend into an uppermost one of the first interlayer dielectric layers ILDa and a portion of the source structure SCP. For example, the buried dielectric pattern VI and the vertical semiconductor pattern VSP of the first vertical channel structure VSa may extend vertically above a top surface of the uppermost one of the first interlayer dielectric layers ILDa. The data storage pattern DSP of the first vertical channel structure VSa may be provided in the uppermost one of the first interlayer dielectric layers ILDa, and may be coplanar with the top surface of the uppermost one of the first interlayer dielectric layers ILDa. Thus, the vertical semiconductor pattern VSP of the first vertical channel structure VSa may be in direct contact with the source structure SCP, and the data storage pattern DSP may be provided in the shape of a vertically extending pipe whose opposite ends are opened.

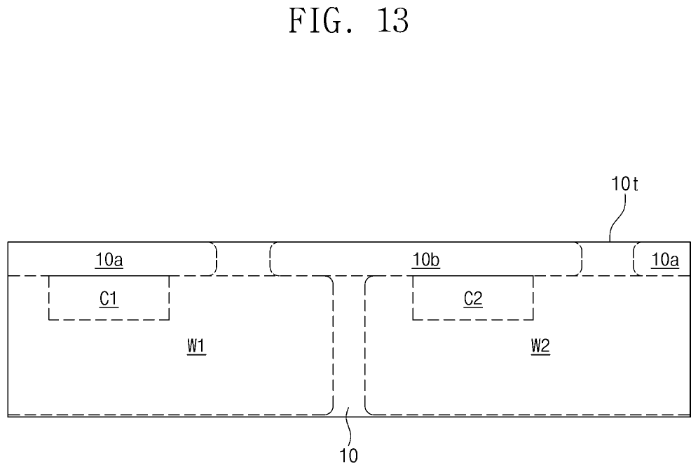

FIGS. 13 to 18 illustrate cross-sectional views showing intermediate processes in an example method of fabricating a semiconductor device according to one or more embodiments of the present inventive concepts.

Referring to FIG. 13, a first well region W1 and a second well region W2 may be formed, a first channel region C1 and a second channel region C2 may be formed, and then first impurity regions 10a and a second impurity region 10b may be formed.

The formation of the first well region W1 may include forming a mask to partially expose a top surface 10t of a first substrate 10 (e.g., using a photolithographic process) and using an ion implantation process to dope the first substrate 10 with impurities having a second conductivity type. Thus, the first well region W1 may be formed in a portion of the first substrate 10. Afterwards, the second well region W2 may be formed in the first substrate 10, and the formation of the second well region W2 may be substantially the same as the formation of the first well region W1. The second well region W2 may be horizontally spaced apart from the first well region W1, and may have a conductivity type opposite to that of the first well region W1.

The formation of the first and second channel regions C1 and C2 may be substantially the same as the formation of the first and second well regions W1 and W2. The first channel region C1 may have the same conductivity type as that of the first well region W1, and may be formed in the first well region W1, proximate an upper surface of the first well region W1. The first channel region C1 may have an impurity concentration greater than that of the first well region W1. The second channel region C2 may have the same conductivity type as that of the second well region W2, and may be formed in the second well region W2, proximate an upper surface of the second well region W2. The second channel region C2 may have an impurity concentration greater than that of the second well region W2. The first and second channel regions C1 and C2 may have different conductivity types from each other.

The first impurity regions 10a and the second impurity region 10b may be formed adjacent to the top surface 10t of the first substrate 10. The first and second impurity regions 10a and 10b may be positioned on the first and second well regions W1 and W2. In a manner similar to the formation of the first and second well regions W1 and W2 and the formation of the first and second channel regions C1 and C2, an ion implantation process may be used to form the first and second impurity regions 10a and 10b. The first impurity regions 10a may have a first conductivity type, and the second impurity region 10b may have a second conductivity type.

For example, the first well region W1, the first channel region C1, and the second impurity region 10b may have a second conductivity type (e.g., p-type), and the second well region W2, the second channel region C2, and the first impurity regions 10a may have a first conductivity type (e.g., n-type).

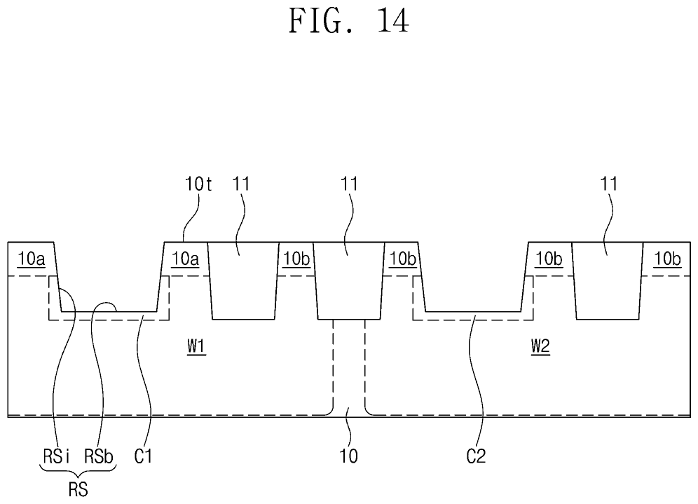

Referring to FIG. 14, device isolation layers 11 may be formed to define an active section on the first substrate 10. The device isolation layers 11 may be positioned between the first and second impurity regions 10a and 10b and between the second impurity regions 10b. The device isolation layers 11 may be formed by using a device isolation process such as a shallow trench isolation (STI) process. The formation of the device isolation layers 11 may include forming a mask pattern to partially expose the top surface 10t of the first substrate 10, performing an etching process using the mask pattern to form a trench, filling the trench with a dielectric material, and then performing a planarization process. The term “filling” (or “fill,” “filled,” or like terms), as may be used herein, is intended to refer broadly to either completely filling a defined space (e.g., the trench forming the device isolation layers 11) or partially filling the defined space; that is, the defined space need not be entirely filled but may, for example, be partially filled or have voids or other spaces throughout.

Afterwards, a portion of the first substrate 10 may be removed to form recess regions RS. The recess regions RS may be horizontally spaced apart from the device isolation layers 11. Each of the recess regions RS may have a bottom surface RSb and inner sidewalls RSi. The recess regions RS may be formed by an etching process using a mask pattern that exposes a portion of the top surface 10t of the first substrate 10. Portions of the first and second impurity regions 10a and 10b and portions of the first and second channel regions C1 and C2 may be removed to form the recess regions RS. Thus, the first impurity regions 10a or the second impurity regions 10b may be positioned on opposite sides of the recess region RS, the first channel region C1 or the second channel region C2 may be below the recess region RS.

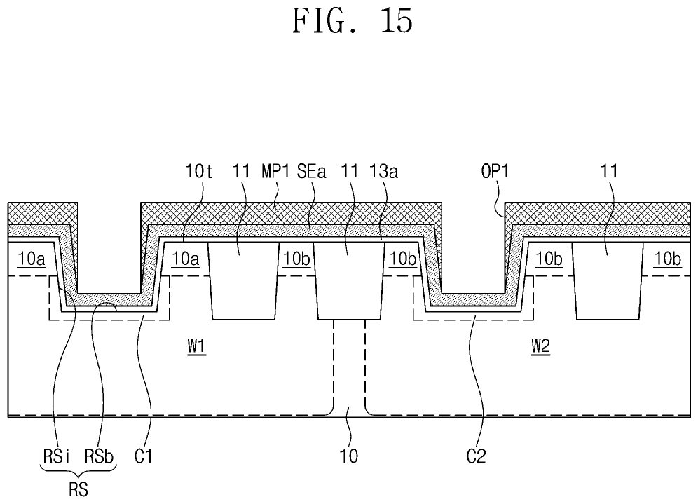

Referring to FIG. 15, a first preliminary dielectric layer 13a and a first preliminary conductive layer SEa may be formed on the first substrate 10. A deposition process may be used to form the first preliminary dielectric layer 13a and the first preliminary conductive layer SEa. For example, the deposition process may include a chemical vapor deposition (CVD) process, a physical vapor deposition (PVD) process, or an atomic layer deposition (ALD) process.

The first preliminary dielectric layer 13a may have a uniform cross-sectional thickness on the top surface 10t of the first substrate 10 and is also on the bottom surfaces RSb and the inner sidewalls RSi of the recess regions RS. The first preliminary conductive layer SEa may be formed to have a uniform cross-sectional thickness on the first preliminary dielectric layer 13a. The first preliminary conductive layer SEa may have a thickness greater than that of the first preliminary dielectric layer 13a. For example, the first preliminary dielectric layer 13a may include at least one selected from silicon nitride and silicon oxynitride, and the first preliminary conductive layer SEa may include at least one selected from impurity-doped semiconductors (e.g., doped polysilicon), metals (e.g., tungsten, copper, or aluminum), conductive metal nitrides (e.g., titanium nitride or tantalum nitride), and transition metals (e.g., titanium or tantalum).

A first mask pattern MP1 may be formed on the first preliminary conductive layer SEa. The first mask pattern MP1 may have a first opening OP1. The first opening OP1 may expose a portion of the first preliminary conductive layer SEa that vertically overlaps the bottom surfaces RSb of the recess regions RS.

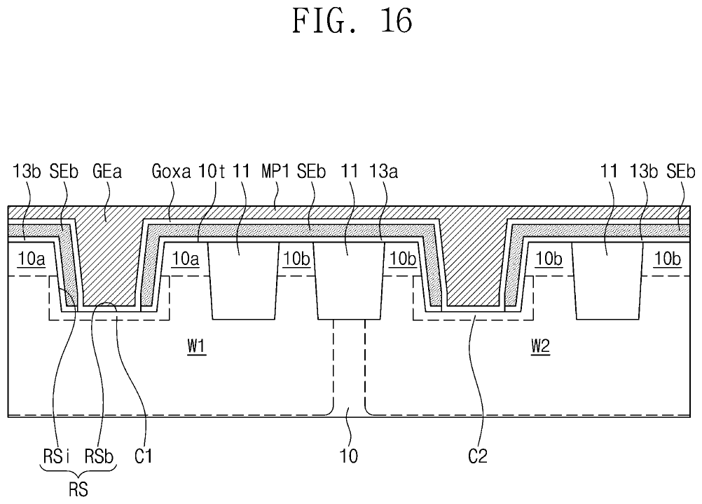

Referring to FIG. 16, an anisotropic etching process using the first mask pattern MP1 may be employed to remove a portion of the first preliminary dielectric layer 13a and a portion of the first preliminary conductive layer Sea (see FIG. 15). Thus, the first preliminary dielectric layer 13a may be formed into second preliminary dielectric layers 13b, and the first preliminary conductive layer SEa may be formed into second preliminary conductive layers SEb. The anisotropic etching process may outwardly expose the bottom surfaces RSb of the recess regions RS.

A preliminary gate dielectric layer Goxa may be formed. The preliminary gate dielectric layer Goxa may have a uniform cross-sectional thickness that covers the second preliminary conductive layers SEb and the bottom surfaces RSb of the recess regions RS. A portion of the preliminary gate dielectric layer Goxa may be in contact with the second preliminary dielectric layers 13b. The preliminary gate dielectric layer Goxa may have a cross-sectional thickness substantially the same as those of the second preliminary dielectric layers 13b. The preliminary gate dielectric layer Goxa may include one or more of silicon oxide, silicon nitride, silicon oxynitride, and low-k dielectric materials.

A preliminary gate electrode GEa may be formed on the preliminary gate dielectric layer Goxa. The preliminary gate electrode GEa may at least partially fill the recess regions RS, while covering the preliminary gate dielectric layer Goxa. The preliminary gate electrode GEa may include, for example, at least one material selected from impurity-doped semiconductors (e.g., doped polysilicon), metals (e.g., tungsten, copper, or aluminum), conductive metal nitrides (e.g., titanium nitride or tantalum nitride), and transition metals (e.g., titanium or tantalum).

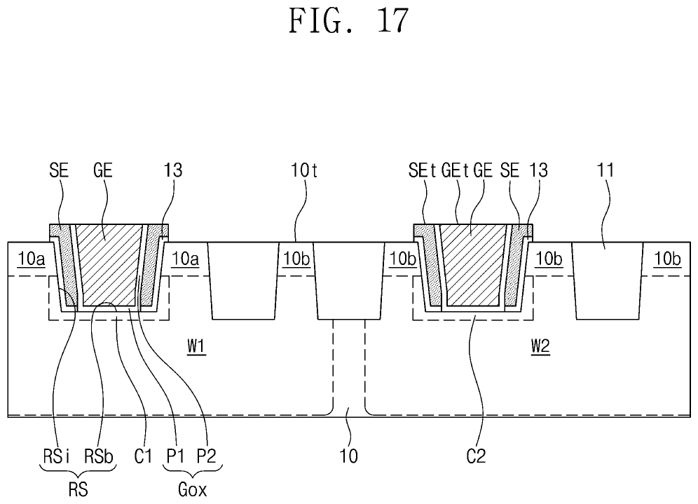

Referring to FIG. 17, a planarization process may be performed until the second preliminary conductive layers SEb (see FIG. 16) are outwardly exposed. The planarization process may remove a portion of the preliminary gate electrode GEa and a portion of the preliminary gate dielectric layer Goxa shown in FIG. 16. Thus, gate electrodes GE and gate dielectric layers Gox may be formed. The preliminary gate electrode GEa (FIG. 16) may be formed into the gate electrodes GE, and the preliminary gate dielectric layer Goxa (FIG. 16) may be formed into the gate dielectric layers Gox. The planarization process may include, for example, a chemical mechanical polishing (CMP) process or an etch-back process.

A patterning process may be performed on the second preliminary conductive layers SEb and the second preliminary dielectric layers 13b shown in FIG. 16. The patterning process may outwardly expose the device isolation layers 11 and the first and second impurity regions 10a and 10b. The patterning process may partially remove the second preliminary conductive layers SEb (FIG. 16) and the second preliminary dielectric layers 13b (FIG. 16). Thus, shield electrodes SE and dielectric patterns 13 may be formed. For example, the second preliminary conductive layers SEb may be formed into the shield electrodes SE, and the second preliminary dielectric layers 13b may be formed into the dielectric patterns 13.

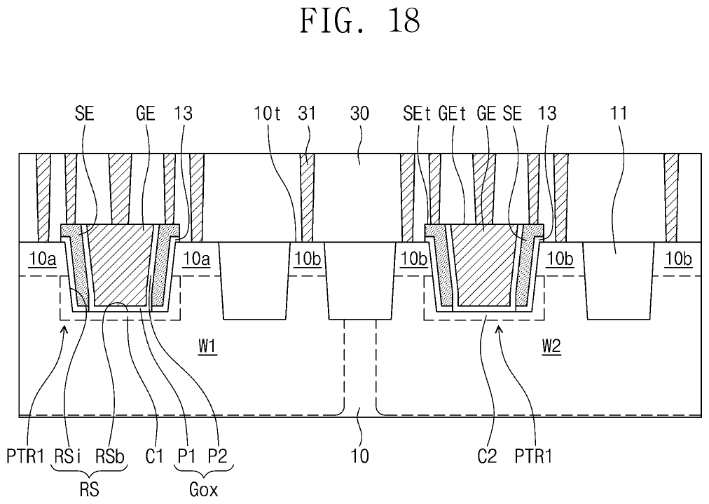

Referring to FIG. 18, a lower dielectric layer 30 and peripheral contact plugs 31 may be formed. The lower dielectric layer 30 may be formed over the first substrate 10, the gate electrodes GE, the gate dielectric layers Gox, the shield electrodes SE, and the dielectric patterns 13. The peripheral contact plugs 31 may extend vertically into the lower dielectric layer 30. The peripheral contact plugs 31 may be correspondingly connected to the first and second impurity regions 10a and 10b, the shield electrodes SE, and the gate electrodes GE.

Thus, first peripheral circuit transistors PTR1 of a semiconductor device may be formed, and each of the first peripheral circuit transistors PTR1 may be an NMOS transistor or a PMOS transistor.

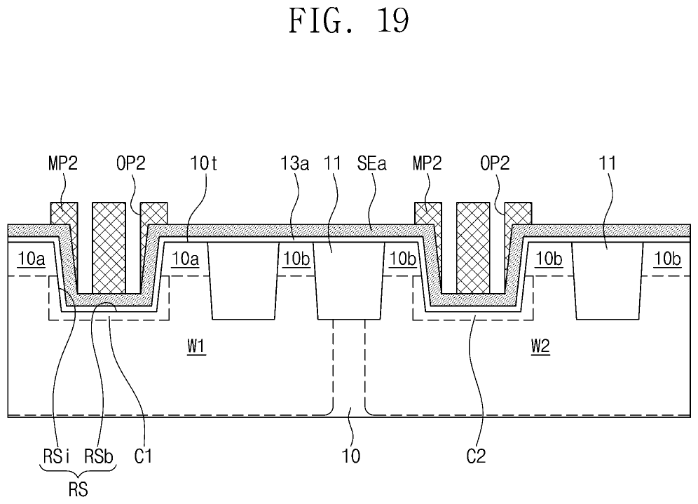

FIGS. 19 to 21 illustrate cross-sectional views showing a method of fabricating a semiconductor device according to some embodiments of the present inventive concepts.

Referring to FIG. 19, first and second well regions W1 and W2, first and second channel regions C1 and C2, first and second impurity regions 10a and 10b, and device isolation layers 11 may be formed in a first substrate 10. Recess regions RS may be formed on a top surface 10t of the first substrate 10, and a first preliminary dielectric layer 13a and a first preliminary conductive layer SEa may be formed over the recess regions RS. The formation of the first and second well regions W1 and W2, the first and second channel regions C1 and C2, the first and second impurity regions 10a and 10b, the device isolation layers 11, the recess regions RS, the first preliminary dielectric layer 13a, and the first preliminary conductive layer SEa may be substantially the same as that discussed in FIGS. 13 to 15.

A second mask pattern MP2 may be formed on a portion of the first preliminary conductive layer SEa. The second mask pattern MP2 may have a second opening OP2. The second opening OP2 may expose the first preliminary conductive layer SEa that partially vertically overlaps the top surface 10t of the first substrate 10 and bottom surfaces RSb of the recess regions RS. The second mask pattern MP2 may vertically overlap the inner sidewalls RSi of the recess regions RS. In some embodiments, the second mask pattern MP2 may partially vertically overlap the inner sidewalls RSi of the recess regions RS. The second mask pattern MP2 may have a different shape from that of the first mask pattern MP1 depicted in FIG. 15.

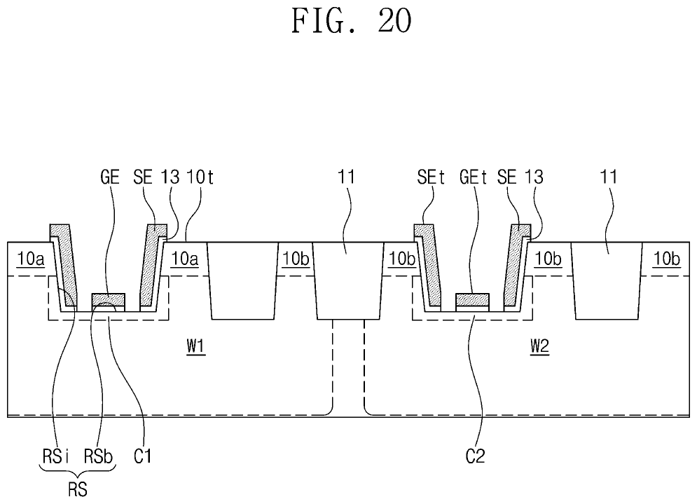

Referring to FIG. 20, an etching process may be performed in which the second mask pattern MP2 may be used to form gate electrodes GE, shield electrodes SE, gate dielectric layers Gox, and dielectric patterns 13 in the recess regions RS. The etching process may outwardly expose a portion of the bottom surface RSb of the recess region RS, the first and second impurity regions 10a and 10b, and the device isolation layers 11. For example, the first preliminary conductive layer SEa may be simultaneously formed into the gate electrodes GE and the shield electrodes SE, and the first preliminary dielectric layer 13a may be simultaneously formed into the gate dielectric layers Gox and the dielectric patterns 13.

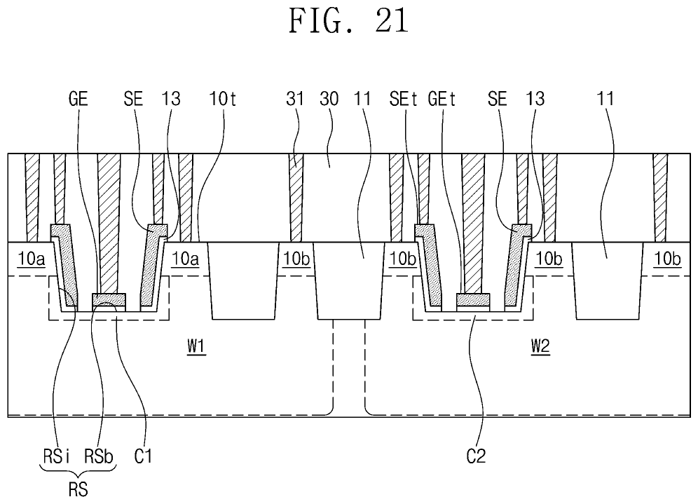

Referring to FIG. 21, a lower dielectric layer 30 and peripheral contact plugs 31 may be formed. The lower dielectric layer 30 may at least partially fill spaces between the gate electrodes GE and the shield electrodes SE and unoccupied portions of the recess regions RS, while covering the first substrate 10. The peripheral contact plugs 31 may extend vertically into the lower dielectric layer 30 to correspondingly come into connection with the first and second impurity regions 10a and 10b, the shield electrodes SE, and the gate electrodes GE.

A semiconductor device according to some embodiments of the present inventive concepts may include a gate electrode and shield electrodes in a recess region, and may also include impurity regions positioned on opposite sides of the recess region. In accordance with operation of a transistor, different voltages may be applied to the shield electrodes to prevent or reduce a leakage current between the gate electrode and the impurity regions. The semiconductor device may thus have improved electrical properties.

Although the present invention has been described in connection with the embodiments of the present invention illustrated in the accompanying drawings, it will be understood to those skilled in the art that various changes and modifications may be made without departing from the technical spirit and essential feature of the present invention. It therefore will be understood that the embodiments described above are just illustrative but not limitative in all aspects.

What is claimed is:

1. A semiconductor device, comprising:
a substrate that has a recess region therein;
a gate electrode on a bottom surface of the recess region;
a gate dielectric layer between the gate electrode and the bottom surface of the recess region;
a plurality of shield electrodes on laterally opposite sides of the gate electrode and on inner sidewalls of the recess region;
a plurality of dielectric patterns between the plurality of shield electrodes and the inner sidewalls of the recess region;
a plurality of impurity regions in the substrate and on laterally opposite sides of the plurality of shield electrodes; and
a channel region in the substrate and below at least a portion of the bottom surface of the recess region.

2. The semiconductor device of claim 1, wherein the gate dielectric layer comprises:
a first portion on the bottom surface of the recess region; and
a plurality of second portions between the gate electrode and the plurality of shield electrodes, each of the plurality of second portions extending vertically along a side of the gate electrode.

3. The semiconductor device of claim 2, wherein the first portion of the gate dielectric layer includes a material different from a material of the plurality of second portions of the gate dielectric layer.

4. The semiconductor device of claim 2, wherein each of the plurality of second portions of the gate dielectric layer includes an air gap.

5. The semiconductor device of claim 1, wherein each of the plurality of impurity regions has a conductivity type different from a conductivity type of the channel region.

6. The semiconductor device of claim 1, wherein the plurality of impurity regions are higher than the bottom surface of the recess region.

7. The semiconductor device of claim 1, wherein
a top surface of the gate electrode is coplanar with top surfaces of the plurality of shield electrodes, and
the top surface of the gate electrode is vertically higher than a top surface of the substrate.

8. The semiconductor device of claim 1, wherein each of the plurality of shield electrodes extends laterally onto a top surface of the substrate and on the plurality of impurity regions.

9. The semiconductor device of claim 1, wherein the channel region extends along the bottom surface and the inner sidewalls of the recess region.

10. The semiconductor device of claim 1, wherein each of the plurality of impurity regions includes an upper impurity region and a lower impurity region,
wherein an impurity concentration of the upper impurity region is greater than an impurity concentration of the lower impurity region.

11. A semiconductor device, comprising:
a substrate that includes a cell array region and a contact region, the substrate having a recess region therein;
a peripheral circuit structure on a top surface of the substrate and including a plurality of peripheral circuit transistors;
a stack structure that includes a plurality of interlayer dielectric layers and a plurality of electrodes, the interlayer dielectric layers and the electrodes being alternately stacked on the peripheral circuit structure in a vertical direction perpendicular to the top surface of the substrate; and
a plurality of vertical channel structures that extend into the stack structure,
wherein the plurality of peripheral circuit transistors includes a first peripheral circuit transistor and a second peripheral circuit transistor, and
wherein the first peripheral circuit transistor includes:
a first gate electrode on a bottom surface of the recess region; and
a plurality of shield electrodes on laterally opposite sides of the first gate electrode and inner sidewalls of the recess region.

12. The semiconductor device of claim 11, wherein the second peripheral circuit transistor includes a second gate electrode on the top surface of the substrate.

13. The semiconductor device of claim 11, wherein the first peripheral circuit transistor further includes:
a gate dielectric layer between the first gate electrode and the bottom surface of the recess region;
a plurality of impurity regions extending in a horizontal direction parallel to the top surface of the substrate on opposite sides of the recess region; and
a channel region below the bottom surface of the recess region.

14. The semiconductor device of claim 13, wherein the gate dielectric layer extends between the first gate electrode and the plurality of shield electrodes.

15. The semiconductor device of claim 11, wherein a top surface of the first gate electrode is vertically lower than the top surface of the substrate.

16. The semiconductor device of claim 11, wherein the plurality of shield electrodes extend from the inner sidewalls of the recess region onto the top surface of the substrate.

17. An electronic system, comprising:
a semiconductor device that includes a substrate having a recess region therein, a peripheral circuit structure including a peripheral circuit transistor on the substrate, a cell array structure including a stack structure on the peripheral circuit transistor, and an input/output pad electrically connected to the peripheral circuit transistor; and
a controller electrically connected through the input/output pad to the semiconductor device, the controller configured to control the semiconductor device,
wherein the peripheral circuit transistor includes:
a gate dielectric layer on a bottom surface of the recess region;
a gate electrode on the gate dielectric layer;
a plurality of dielectric patterns on inner sidewalls of the recess region; and
a plurality of shield electrodes between the plurality of dielectric patterns and the gate electrode.

18. The electronic system of claim 17, wherein
the peripheral circuit structure includes a first bonding pad electrically connected to the peripheral circuit transistor, and
the cell array structure includes a second bonding pad in contact with the first bonding pad.

19. The electronic system of claim 17, wherein the peripheral circuit transistor further includes:
a plurality of impurity regions extending in a horizontal direction parallel to a top surface of the substrate on opposite sides of the recess region; and
a channel region below the bottom surface of the recess region,
wherein the plurality of impurity regions have a conductivity type different from a conductivity type of the channel region.

20. The electronic system of claim 17, wherein top surfaces of the plurality of shield electrodes are vertically higher than a top surface of the substrate.
